(19) United States
(12) Patent Application Publication
(10) Pub. No.: US 2025/0137118 A1
(43) Pub. Date: May 1, 2025

(54) POLYMERIC INHIBITOR FOR AREA SELECTIVE DEPOSITION

(71) Applicant: ASM IP Holding B.V., Almere (NL)

(72) Inventors: Eric James Shero, Phoenix, AZ (US); Marko Tuominen, Helsinki (FI); Charles Dezelah, Helsinki (FI)

(21) Appl. No.: 18/926,748

(22) Filed: Oct. 25, 2024

Related U.S. Application Data
(60) Provisional application No. 63/546,475, filed on Oct. 30, 2023.

(51) Int. Cl. C23C 16/04

(52) U.S. Cl. CPC C23C 16/04

(57) ABSTRACT

Methods and apparatus are disclosed for forming a passivation layer on a substrate, comprising, providing the substrate in a reaction chamber, the substrate comprising a first surface and a second surface, contacting the substrate with a first precursor comprising an amine compound comprising at least two amine groups and contacting the substrate with a second precursor comprising at least one thioanhydride, wherein contacting the substrate with the first and second precursors forms the film selectively on the first surface relative to the second surface.

### CROSS-REFERENCE TO RELATED APPLICATIONS

This application is a nonprovisional of, and claims priority to and the benefit of, U.S. Provisional Patent Application No. 63/546,475, filed Oct. 30, 2023 and entitled “IMPROVED POLYMERIC INHIBITOR FOR AREA SELECTIVE DEPOSITION,” which is hereby incorporated by reference herein.

### FIELD

The present disclosure relates to deposition of organic thin films, including selective deposition on a first surface of a substrate relative to a second surface.

### DESCRIPTION OF RELATED ART

Shrinking device dimensions in semiconductor manufacturing call for new innovative processing approaches. Conventionally, patterning in semiconductor processing involves subtractive processes, in which blanket layers are deposited, masked by photolithographic techniques, and etched through openings in the mask. Additive patterning is also known, in which masking steps precede deposition of the materials of interest, such as patterning using lift-off techniques or damascene processing. In most cases, expensive multi-step lithographic techniques are applied for patterning.

Selective deposition, which is receiving increasing interest among semiconductor manufacturers, could enable a decrease in steps needed for conventional patterning, reducing the cost of processing. Selective deposition could also allow enhanced scaling in narrow structures. Various alternatives for bringing about selective deposition have been proposed, and additional improvements are needed to expand the use of selective deposition in industrial-scale device manufacturing. A need exists for more efficient and reliable techniques for improving selectivity and decreasing defectivity in selective deposition.

Any discussion, including discussion of problems and solutions, set forth in this section has been included in this disclosure solely for the purpose of providing a context for the present disclosure. Such discussion should not be taken as an admission that any of the information was known at the time the subject-matter of the disclosure was conceived or otherwise constitutes prior art.

### BRIEF SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Methods and apparatus are disclosed for forming a passivation layer on a substrate, comprising, providing the substrate in a reaction chamber, the substrate comprising a first surface and a second surface, contacting the substrate with a first precursor comprising an amine compound comprising at least two amine groups and contacting the substrate with a second precursor comprising at least one thioanhydride, wherein contacting the substrate with the first and second precursors forms the film selectively on the first surface relative to the second surface.

In some examples, the passivation layer comprises a polyimide film. In some examples, the passivation layer comprises a polyimide film pyromellitic dithioanhydride.

In some examples, the contacting operations comprise a deposition cycle, the process comprising one or more deposition cycles.

In certain examples, the contacting operations further comprise repeating the contacting operations until a passivation layer of a desired thickness has been formed.

In various examples, the first surface is a metal carbide, metal oxide, metal nitride, metal boride, elemental metal, metallic surface, amorphous carbon, or a combination thereof.

In some examples, the first surface comprises a metal comprising aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr) or vanadium (V), or a combination thereof.

In various examples, the first surface is a dielectric surface comprising SiCOx, SiOx, silicon, SiO2, zirconium oxide (ZrO2), hafnium oxide (HfO2), aluminum oxide (Al2O3), titanium nitride (TiN) and titanium oxide (TiO2), or aluminum nitride (AlN), or a combination thereof.

In some examples, the first surface comprises RuOx, NiOx, CoOx, NbOx, MoOx, WOx, NbBx, NbCx, WNCx, TaN, or TiN, or a combination thereof.

In various examples, the second surface comprises a passivation blocking layer formed thereon.

In certain examples, the second surface comprises a metal comprising aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr) or vanadium (V), or a combination thereof.

In various examples, the second surface is a dielectric surface comprising SiCOx, SiOx, silicon, SiO2, zirconium oxide (ZrO2), hafnium oxide (HfO2), aluminum oxide (Al2O3), titanium nitride (TiN) and titanium oxide (TiO2), or aluminum nitride (AlN), or a combination thereof.

In some examples, the second surface comprises RuOx, NiOx, CoOx, NbOx, MoOx, WOx, NbBx, NbCx, WNCx, TaN, or TiN, or a combination thereof.

In certain examples, the passivation blocking layer comprises a self-assembled monolayer (SAM) or an alkylsilane having at least one alkoxy group bonded to a silicon atom.

In various examples, the first precursor comprises a diamine, a triamine, a tetraamine, a cyclic compound comprising at least two primary amines, or a combination thereof.

In some examples, the second precursor comprises a compound including two thioanhydride groups comprising a structure represented by the general formula (1):

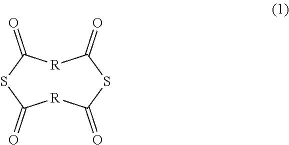

where R and R′ independently comprise hydrocarbyl groups. In various examples, at least one of the hydrocarbyl groups independently comprises one or more of O, N, or S, or a combination thereof.

In certain examples, the second precursor comprises a compound including two thioanhydride groups comprising a structure represented by the general formula (2):

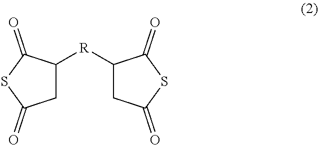

where R comprises a hydrocarbyl group. In various examples, the hydrocarbyl group comprises one or more of O, N, or S, or a combination thereof.

In some examples, the second precursor comprises a compound including one thioanhydride group and one anhydride group comprising a structure represented by the general formula (3):

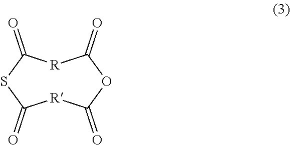

where R and R′ independently comprise hydrocarbyl groups. In various examples, wherein at least one of the hydrocarbyl groups independently comprises one or more of O, N, or S, or a combination thereof.

In various examples, the second precursor comprises a compound including one thioanhydride group and one anhydride group comprising a structure represented by the general formula (4):

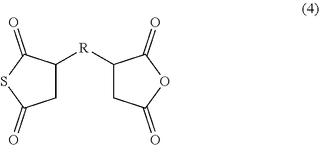

where R comprises a hydrocarbyl group. In various examples, the hydrocarbyl group comprises one or more of O, N, or S, or a combination thereof.

In various examples, the second precursor comprises a compound including at least one thioanhydride group comprising a structure represented by the general formula (5):

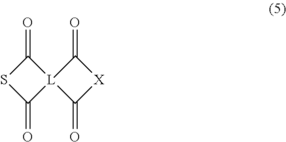

where L is a tetravalent hydrocarbyl group that optionally comprises one or more of O, N, or S, or a combination thereof; and where X is selected from the group consisting of S or O.

In some examples, the second precursor comprises a compound including two or more anhydride groups comprising a structure represented by the general formula (6):

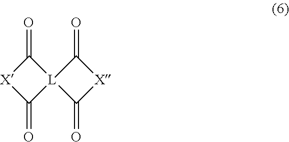

where L is a tetravalent hydrocarbyl group that optionally comprises one or more of O, N, or S, or a combination thereof; and where X′ and X″ are independently selected from the group consisting of S, Se, Te, NH, NR″ or O, where R″ is a C1 to C6 compound.

In certain examples, the second precursor comprises a compound represented by the general formula (7):

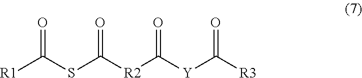

where R1, R2 and R3 independently comprise hydrocarbyl groups that optionally comprises one or more of O, N, or S, or a combination thereof; and where Y is selected from the group consisting of S, Se, Te, NH, NR″ or O, where R″ is a C1 to C6 compound.

In some examples, the process further comprises selectively depositing a material on the second surface of the substrate relative to the passivation layer.

In various examples, the material is a first dielectric and the second surface is a second dielectric.

In certain examples, the material is a dielectric and the second surface is a metal.

In some examples, the material is a metal and the second surface is a dielectric.

In various examples, the material is a metal and the second surface is a metal comprising a conductive metal nitride.

For the purpose of summarizing the disclosure and the advantages achieved over the prior art, certain objects and advantages of the disclosure have been described herein above. Of course, it is to be understood that not necessarily all such objects or advantages can be achieved in accordance with any particular embodiment or example of the disclosure. Thus, for example, those skilled in the art will recognize that the examples disclosed herein can be carried out in a manner that achieves or optimizes one advantage or group of advantages as taught or suggested herein without necessarily achieving other objects or advantages as can be taught or suggested herein.

All of these examples are intended to be within the scope of the disclosure. These and other embodiments will become readily apparent to those skilled in the art from the following detailed description of certain examples having reference to the attached figures, the disclosure not being limited to any particular example(s) discussed.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

FIG. 1 is a flow diagram generally illustrating atomic layer deposition (ALD) processes for selectively depositing an organic film.

FIG. 2 is a flow diagram generally illustrating atomic layer deposition (ALD) processes for selectively depositing an organic film.

FIG. 3 is a schematic illustration of an apparatus configured for selective deposition of a polymer layer.

FIG. 4 is a flow diagram generally illustrating atomic layer deposition (ALD) processes for selectively depositing an organic film.

FIG. 5 is a flow diagram generally illustrating atomic layer deposition (ALD) processes for selectively depositing an organic film.

### DETAILED DESCRIPTION

The description of exemplary embodiments of methods, layers, structures, devices and semiconductor processing assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

The headings provided herein, if any, are for convenience only and do not necessarily affect the scope or meaning of the claimed subject-matter.

In one aspect, a method of selectively depositing inhibitor material on a first surface of a substrate relative to a second surface of the substrate is disclosed. The method comprises providing the substrate comprising the first surface and the second surface in a reaction chamber and contacting the substrate with a vapor-phase inhibitor reactant, the inhibitor reactant comprising an alkylsilane having at least one alkoxy group bonded to a silicon atom, wherein the inhibitor reactant selectively forms inhibitor material on the first surface.

As used herein, the term “layer” and/or “film” can refer to any continuous or noncontinuous material, such as material deposited by the methods disclosed herein. For example, layer and/or film can include two-dimensional materials, three-dimensional materials, nanoparticles or even partial or full molecular layers or partial or full atomic layers or clusters of atoms and/or molecules. A film or layer may comprise material or a layer with pinholes, which may be at least partially continuous. In some embodiments, a layer according to the current disclosure is substantially continuous. In some embodiments, a layer according to the current disclosure is continuous.

In this disclosure, “gas” can include material that is a gas at normal temperature and pressure (NTP), a vaporized solid and/or a vaporized liquid, and can be constituted by a single gas or a mixture of gases, depending on the context. Reactants and precursors according to the current disclosure may be provided to the reaction chamber in gas phase. The term “inert gas” can refer to a gas that does not take part in a chemical reaction and/or does not become a part of a layer to an appreciable extent. Exemplary inert gases include He and Ar and any combination thereof. In some cases, molecular nitrogen and/or hydrogen can be an inert gas. A gas other than a process gas, i.e., a gas introduced without passing through a precursor injector system, other gas distribution device, or the like, can be used for, e.g., sealing the reaction chamber, and can include a seal gas.

The term dielectric is used in the description herein for the sake of simplicity in distinguishing from metal or metallic surfaces. It will be understood by those skilled in the art that not all non-conducting surfaces are dielectric surfaces. For example, the metal or metallic surface may comprise an oxidized metal surface that is electrically non-conducting or has a very high resistivity. Selective deposition processes of inhibitor material taught herein can deposit on dielectric surfaces with minimal deposition on such adjacent non-conductive metal or metallic surfaces.

The terms “precursor” and “reactant” can refer to molecules (compounds or molecules comprising a single element) that participate in a chemical reaction that produces another compound or an element. A precursor typically contains portions that are at least partly incorporated into the compound or element resulting from the chemical reaction in question. Such a resulting compound or element may be deposited on a substrate. In some instances, a reactant is a precursor. A reactant may also be a molecule that binds, such as chemisorbs, on the surface of a substrate without undergoing further chemical reactions at the surface with additional precursors and/or reactants. A reactant on a substrate surface may be modified by, for example, thermal or a plasma treatment.

In some embodiments, a precursor or a reactant is provided in a mixture of two or more compounds. In a mixture, the other compounds in addition to the precursor may be inert compounds or elements. In some embodiments, a precursor or a reactant is provided in a composition. Composition may be a solution or a gas in standard conditions.

As used herein, the term “comprising” indicates that certain features are included, but that it does not exclude the presence of other features, as long as they do not render the claim unworkable. In some embodiments, the term “comprising” includes “consisting.”

As used herein, the term “consisting” indicates that no further features are present in the apparatus/method/product apart from the ones following said wording. When the term “consisting” is used referring to a chemical compound, substance, or composition of matter, it indicates that the chemical compound, substance, or composition of matter only contains the components which are listed. Likewise, when the term “consisting essentially” is used referring to a chemical compound, substance, or composition of matter, it indicates that the chemical compound, substance, or composition of matter contains the components which are listed but can also containing trace elements and/or impurities that do not materially affect the characteristics of said chemical compound, substrate, or composition of matter. This notwithstanding, the chemical compound, substance, or composition of matter may, in some embodiments, comprise other components as trace elements or impurities, apart from the components that are listed.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly to this, it will be understood the term “under”, “underlying”, or “below” will be construed to be relative concepts.

### Substrate

The deposition method according to the current disclosure comprises providing a substrate in a reaction chamber. The substrate may be any underlying material or materials that can be used to form, or upon which, a structure, a device, a circuit, or a layer can be formed. A substrate can include a bulk material, such as silicon (e.g., single-crystal silicon), other Group IV materials, such as germanium, or other semiconductor materials, such as a Group II-VI or Group III-V semiconductor materials, and can include one or more layers overlying or underlying the bulk material. Further, the substrate can include various features, such as recesses, protrusions, and the like formed within or on at least a portion of a layer of the substrate. For example, a substrate can include bulk semiconductor material and an insulating or dielectric material layer overlying at least a portion of the bulk semiconductor material. Substrate may include nitrides, for example TiN, oxides, insulating materials, dielectric materials, conductive materials, metals, such as such as tungsten, ruthenium, molybdenum, cobalt, aluminum or copper, or metallic materials, crystalline materials, epitaxial, heteroepitaxial, and/or single crystal materials. In some embodiments of the current disclosure, the substrate comprises silicon. The substrate may comprise other materials, as described above, in addition to silicon. The other materials may form layers. Specifically, the substrate may comprise a partially fabricated semiconductor device.

A substate according to the current disclosure comprises a first surface and a second surface. The first surface and the second surface have different material properties, allowing for the selective deposition of an inhibitor material on the first surface and optionally an organic polymer on the second surface. In some embodiments, the first surface and the second surface are adjacent to each other. In some embodiments, the first surface and the second surface are on the same face of a silicon wafer.

In some embodiments, the substrate may be pretreated or cleaned prior to or at the beginning of the selective deposition process according to the current disclosure. In some embodiments, the substrate may be subjected to a plasma cleaning process at prior to or at the beginning of the selective deposition process. In some embodiments, a plasma cleaning process may not include ion bombardment, or may include relatively small amounts of ion bombardment. For example, in some embodiments, the substrate surface may be exposed to plasma, radicals, excited species, and/or atomic species prior to or at the beginning of the selective deposition process. In some embodiments, the substrate surface may be exposed to hydrogen plasma, radicals, or atomic species prior to or at the beginning of the selective deposition process. In some embodiments, a pretreatment or cleaning process may be carried out in the same reaction chamber as a selective deposition process. However, in some embodiments, a pretreatment or cleaning process may be carried out in a separate reaction chamber.

### Reaction Chamber

The method of depositing inhibitor material according to the current disclosure comprises providing a substrate in a reaction chamber. In other words, a substrate is in a space where the deposition conditions can be controlled. The reaction chamber may be a single wafer reactor. Alternatively, the reaction chamber may be a batch reactor. The reaction chamber can form part of a vapor processing assembly for manufacturing semiconductor devices, such as a semiconductor processing assembly. The semiconductor processing assembly may comprise one or more multi-station processing chambers. The reaction chamber may be part of a cluster tool in which different processes are performed to form an integrated circuit. Various phases of the methods according to the current disclosure, such as methods of depositing an organic polymer, or methods of depositing dielectric material, can be performed within a single reaction chamber, or they can be performed in multiple reaction chambers, such as reaction chambers of a cluster tool, or deposition stations of a multi-station processing chamber.

In some embodiments, the reaction chamber may be a flow-type reactor, such as a cross-flow reactor. In some embodiments, the reaction chamber may be a showerhead reactor. In some embodiments, the reaction chamber may be a hot-wall reactor. In some embodiments, the reaction chamber may be a space-divided reactor. In some embodiments, the reaction chamber may be a single-wafer ALD reactor. In some embodiments, the reaction chamber may be a high-volume manufacturing single-wafer ALD reactor. In some embodiments, the reaction chamber may be a batch reactor for manufacturing multiple substrates simultaneously.

The reaction chamber of the current disclosure can form part of an atomic layer deposition (ALD) assembly. The reaction chamber can form part of a chemical vapor deposition (CVD) assembly. The processing assembly may be an ALD or a CVD processing assembly. In some parts of the deposition process flow, molecular layer deposition (MLD) may be employed. In some embodiments, the method is performed in a single reaction chamber of a cluster tool, but other, preceding or subsequent, manufacturing steps of the structure or device are performed in additional reaction chambers of the same cluster tool. Optionally, a semiconductor processing assembly including the reaction chamber can be provided with a heater to activate the reactions by elevating the temperature of one or more of the substrate and/or the reactants and/or precursors.

### Cyclic Vapor Deposition

In some methods according to the current disclosure, particularly those of depositing an organic polymer, and dielectric material, cyclic vapor deposition methods may be used. Cyclic deposition in the current disclosure refers to vapor deposition processes in which deposition cycles, typically a plurality of consecutive deposition cycles, are conducted in a process chamber. For clarity, the deposition of inhibitor material according to the current disclosure may be a non-cyclic process, in which the inhibitor reactant

Generally, in cyclic deposition processes according to the current disclosure, such as atomic layer deposition (ALD) and molecular layer deposition (MLD), during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. Without limiting the current disclosure to any specific theory, ALD and MLD may be similar processes in terms of self-limiting reactions and slower and more controllable layer growth speed compared to CVD. Generally, ALD is used to deposit inorganic materials, such as a dielectric material, whereas in MLD, the precursors may be fully organic molecules, such as when an organic polymer is deposited.

In some embodiments, the process according to the current disclosure may contain a CVD component. CVD-type processes may be characterized by vapor deposition which is not self-limiting. They typically involve gas phase reactions between two or more precursors and/or reactants. The precursor(s) and reactant(s) can be provided simultaneously to the reaction chamber or substrate, or in partially or completely separated pulses. However, CVD may be performed with a single precursor, or two or more precursors that do not react with each other. A single precursor may decompose into reactive components that are deposited on the substrate surface. The decomposition may be brought about by plasma or thermal means, for example. The substrate and/or reaction chamber can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap. The process may comprise one or more cyclic phases. In some embodiments, the process comprises or one or more acyclic (i.e. continuous) phases. An example of a continuous phase could be a pre-treatment with a single reactant. In some embodiments, the deposition process comprises the continuous flow of at least one precursor. In some embodiments, one or more of the precursors are provided in the reaction chamber continuously.

According to some aspects of the present disclosure, selective deposition can be used to deposit a material on a first surface relative to a second surface. The two surfaces can have different material properties.

In some examples an organic material such as a polyamide or polyimide is selectively deposited on a first conductive (e.g., metal or metallic) surface of a substrate relative to a second dielectric surface of the substrate. In some examples the second surface comprises-OH groups, such as a silicon oxide-based surface. In some examples the second surface may additionally comprise —H terminations, such as an HF dipped Si or HF dipped Ge surface. In such examples, the surface of interest will be considered to comprise both the —H terminations and the material beneath the —H terminations. In some examples an organic material such as a polyamide or polyimide is selectively deposited on a first dielectric surface of a substrate relative to a second, different dielectric surface. In some such examples, the dielectrics have different compositions (e.g., silicon, silicon nitride, carbon, silicon oxide, silicon oxynitride, germanium oxide). In other such examples, the dielectrics can have the same basic composition (e.g., silicon oxide-based layers) but different material properties due to the manner of formation (e.g., thermal oxides, native oxides, deposited oxides). In some examples vapor deposition methods are used. In some examples cyclical vapor deposition is used, for example, cyclical CVD or atomic layer deposition (ALD) processes are used. After selective deposition of the organic material is completed, further processing can be carried out to form the desired structures.

For examples in which one surface comprises a metal whereas the other surface does not, unless otherwise indicated, if a surface is referred to as a metal surface herein, it may be a metal surface or a metallic surface. In some examples the metal or metallic surface may comprise metal, metal oxides, and/or mixtures thereof. In some examples the metal or metallic surface may comprise surface oxidation. In some examples the metal or metallic material of the metal or metallic surface is electrically conductive with or without surface oxidation. In some examples metal or a metallic surface comprises one or more transition metals. In some examples a metal or metallic surface comprises aluminum. In some examples the metal or metallic surface comprises one or more of aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr) or vanadium (V), or a combination thereof. In some examples a metallic surface comprises titanium nitride. In some examples the metal or metallic surface comprises one or more noble metals, such as Ru. In some examples the metal or metallic surface comprises a conductive metal oxide, nitride, carbide, boride, or combination thereof. For example, the metal or metallic surface may comprise one or more of RuOx, NbCx, NbBx, NiOx, CoOx, NbOx, WNCx, TaN, MoNx, WNx, AlOx, and/or TiN.

In some examples the metal or metallic surface may comprise Zn, Fe, Mn, or Mo. In some examples the metal or metallic surface may be any surface that can accept or coordinate with the first or second precursor utilized in a selective deposition process as described herein.

In some examples an organic material is selectively deposited on a metal oxide surface relative to other surfaces. A metal oxide surface may be, for example a WOₓ, HfOₓ, TiOₓ, AlOₓ or ZrOₓ, surface. In some examples a metal oxide surface is an oxidized surface of a metallic material. In some examples a metal oxide surface is created by oxidizing at least the surface of a metallic material using oxygen compound, such as compounds comprising O₃, H₂O, H₂O₂, O₂, oxygen atoms, plasma or radicals or mixtures thereof. In some examples a metal oxide surface is a native oxide formed on a metallic material.

In some examples the first surface may comprise a passivated metal surface, for example a passivated Cu surface. That is, in some examples the first surface may comprise a metal surface comprising a passivation layer, for example an organic passivation layer such as a benzotriazole (BTA) layer.

In some examples an organic material is selectively deposited on a first dielectric surface relative to a second SiO2 surface. In some examples an organic material is selectively deposited on a first dielectric surface relative to a second Si or Ge surface, for example an HF-dipped Si or HF-dipped Ge surface.

In some examples an organic material is selectively deposited on a first metal or metallic surface of a substrate relative to a second dielectric surface of the substrate. In some examples the organic material that is selectively deposited is a polyamide, polyimide, or other polymeric material. The term dielectric is used in the description herein for the sake of simplicity in distinguishing from the other surface, namely the metal or metallic surface. It will be understood by the skilled artisan that not all non-conducting surfaces are dielectric surfaces. For example, the metal or metallic surface may comprise an oxidized metal surface that is electrically non-conducting or has a very high resistivity. Selective deposition processes taught herein can deposit on such non-conductive metallic surfaces with minimal deposition on adjacent dielectric surfaces.

In some examples an organic material is selectively deposited on a first metal oxide surface of a substrate relative to a second SiO₂ surface. In some examples the first metal oxide surface may be, for example a WOₓ, HfOₓ, TiOₓ, AlOₓ or ZrOₓ surface. In some examples the organic material is deposited on a first dielectric surface relative to a second SiO₂ surface. In some examples the second SiO₂ surface may be, for example, a native oxide, a thermal oxide or a chemical oxide. In some examples an organic material is selectively deposited on a first metal oxide surface relative to a second Si or Ge surface, for example an HF-dipped Si or HF-dipped Ge surface.

In some examples a substrate is provided comprising a first metal or metallic surface and a second dielectric surface. In some examples a substrate is provided that comprises a first metal oxide surface. In some examples the second surface may comprise —OH groups. In some examples the second surface may be a SiO₂ based surface. In some examples the second surface may comprise Si—O bonds. In some examples the second surface may comprise a SiO₂ based low-k material. In some examples the second surface may comprise more than about 30%, or more than about 50% of SiO₂. In some examples the second surface may comprise GeO₂. In some examples the second surface may comprise Ge—O bonds. In some examples an organic material is selectively deposited on a first metal or metallic surface relative to a second Si or Ge surface, for example an HF-dipped Si or HF-dipped Ge surface.

In certain examples the first surface may comprise a silicon dioxide surface and the second dielectric surface may comprise a second, different silicon dioxide surface. For example, in some examples the first surface may comprise a naturally or chemically grown silicon dioxide surface. In some examples the second surface may comprise a thermally grown silicon dioxide surface. In other examples, the first or the second surface may be replaced with a deposited silicon oxide layer. Therefore, in some examples organic material may be selectively deposited on a first silicon dioxide surface of a substrate relative to a second silicon dioxide surface that was formed by a different technique and therefore has different material properties.

In some examples the substrate may be pretreated or cleaned prior to or at the beginning of the selective deposition process. In some examples the substrate may be subjected to a plasma cleaning process at prior to or at the beginning of the selective deposition process. In some examples a plasma cleaning process may not include ion bombardment, or may include relatively small amounts of ion bombardment. For example, in some examples the substrate surface may be exposed to plasma, radicals, excited species, and/or atomic species prior to or at the beginning of the selective deposition process. In some examples the substrate surface may be exposed to hydrogen plasma, radicals, or atomic species prior to or at the beginning of the selective deposition process. In some examples a pretreatment or cleaning process may be carried out in the same reaction chamber as a selective deposition process, however in some examples a pretreatment or cleaning process may be carried out in a separate reaction chamber.

The term “about” is employed herein to mean within standard measurement accuracy.

Selective deposition using the methods described herein can advantageously be achieved with treatment of the second dielectric surface to block deposition thereon and/or with treatment of the first surface (whether metallic or a different dielectric surface) to catalyze deposition. As a result, in some examples the second dielectric surface does may comprise a passivation blocking or inhibitor layer, such as a self-assembled monolayer (SAM), which may prevent the top surface of the second dielectric surface from being exposed to the chemicals of the deposition processes described herein. Thus, in some examples selectivity is achieved by use of blocking or catalyzing agents, where one of first or second surfaces are not directly exposed to deposition reactants.

Vapor phase deposition techniques can be applied to organic films and polymers such as polyimide films, polyamide films, polyurea films, polyurethane films, polythiophene films, and more. CVD of polymer films can produce greater thickness control, mechanical flexibility, conformal coverage, and biocompatibility as compared to the application of liquid precursor. Sequential deposition processing of polymers can produce high growth rates in small research scale reactors. Similar to CVD, sequential deposition processes can produce greater thickness control, mechanical flexibility, and conformality. The terms “sequential deposition” and “cyclical deposition” are employed herein to apply to processes in which the substrate is alternately or sequentially exposed to different precursors, regardless of whether the reaction mechanisms resemble ALD, CVD, MLD or hybrids thereof.

In some examples the processes described herein may be batch processes, that is, the processes may be carried out on two or more substrates at the same time. In some examples the processes described herein may be carried out on two or more, five or more, 10 or more, 25 or more, 50 or more, or 100 or more substrates at the same time. In some examples the substrate may comprise wafers, for example, semiconductor or silicon wafers. In some examples the substrates may have diameters of 100 mm or more, 200 mm or more, or 300 mm or more. In some instances substrates having diameters of 450 mm or more may be desirable.

### Selectivity

Selectivity can be given as a percentage calculated by [(deposition on first surface)-(deposition on second surface)]/(deposition on the first surface). Deposition can be measured in any of a variety of ways. In some examples deposition may be given as the measured thickness of the deposited material. In some examples deposition may be given as the measured amount of material deposited.

In some examples selectivity is greater than about 10%, greater than about 50%, greater than about 75%, greater than about 85%, greater than about 90%, greater than about 93%, greater than about 95%, greater than about 98%, greater than about 99% or even greater than about 99.5%. In examples described herein, the selectivity can change over the duration or thickness of a deposition. Surprisingly, selectivity has been found to increase with the duration of the deposition for the vapor phase polymer film depositions described herein. In contrast, typical selective deposition based on differential nucleation on different surfaces tends to become less selective with greater duration or thickness of a deposition.

In some examples deposition only occurs on the first surface and does not occur on the second surface. In some examples deposition on the first surface of the substrate relative to the second surface of the substrate is at least about 80% selective, which may be selective enough for some particular applications. In some examples the deposition on the first surface of the substrate relative to the second surface of the substrate is at least about 50% selective, which may be selective enough for some particular applications. In some examples the deposition on the first surface of the substrate relative to the second surface of the substrate is at least about 10% selective, which may be selective enough for some particular applications.

In some examples the organic film deposited on the first surface of the substrate may have a thickness less than about 50 nm, less than about 20 nm, less than about 10 nm, less than about 5 nm, less than about 3 nm, less than about 2 nm, or less than about 1 nm, while a ratio of material deposited on the first surface of the substrate relative to the second surface of the substrate may be greater than or equal to about 2:1, greater than or equal to about 20:1, greater than or equal to about 15:1, greater than or equal to about 10:1, greater than or equal to about 5:1, greater than or equal to about 3:1, or greater than or equal to about 2:1.

In some examples the selectivity of the selective deposition processes described herein may depend on the materials which comprise the first and/or second surface of the substrate. For example, in some examples where the first surface comprises a BTA passivated Cu surface and the second surface comprises a natural or chemical silicon dioxide surface the selectivity may be greater than about 8:1 or greater than about 15:1. In some examples where the first surface comprises a metal or metal oxide and the second surface comprises a natural or chemical silicon dioxide surface the selectivity may be greater than about 5:1 or greater than about 10:1. In some examples where the first surface comprises a chemical or natural silicon dioxide surface and the second surface comprises a thermal silicon dioxide surface the selectivity may be greater than about 5:1 or greater than about 10:1. In some examples where the first surface comprises natural or chemical silicon dioxide, and the second surface comprises Si—H terminations, for example an HF dipped Si surface, the selectivity may be greater than about 5:1 or greater than about 10:1. In some examples where the first surface comprises Si—H terminations, for example an HF dipped Si surface, and the second surface comprises thermal silicon dioxide, the selectivity may be greater than about 5:1 or greater than about 10:1.

### Selective Deposition

Deposition processes taught herein can achieve high growth rate and throughput, and can produce high quality organic thin films.

In some examples, a substrate comprising a first surface and a second surface is provided. The first and second surfaces may have different material properties. In some examples the first surface may be a metallic surface and the second surface may be a dielectric surface. In some examples a first precursor is vaporized to form a first precursor vapor. The reactant being vaporized may be liquid or solid under standard temperature and pressure conditions (room temperature and atmospheric pressure). In some examples, the reactant being vaporized comprises an organic precursor, such as an amine, for example a diamine, such as 1,6-diamnohexane (DAH), or another organic precursor, such as a dianhydride, for example pyromellitic dianhydride (PMDA) and/or pyromellitic dithioanhydride (PMDTA). The substrate is then exposed to the first precursor vapor and an organic film deposited. The method can include additional steps, and may be repeated, but need not be performed in the illustrated sequence nor the same sequence in each repetition if repeated, and can be readily extended to more complex vapor deposition techniques.

In some examples, the organic film comprises a polymer. In some examples, the polymer deposited is a polyimide. In some examples, the polymer deposited is a polyamide. Other examples of deposited polymers include dimers, trimers, polyurethanes, polythioureas, polyesters, polyimines, other polymeric forms or mixtures of the above materials. The techniques taught herein can be applied to vapor deposition techniques, including CVD, VPD, ALD, and MLD in a wide variety of reactor configurations.

### Selective Deposition

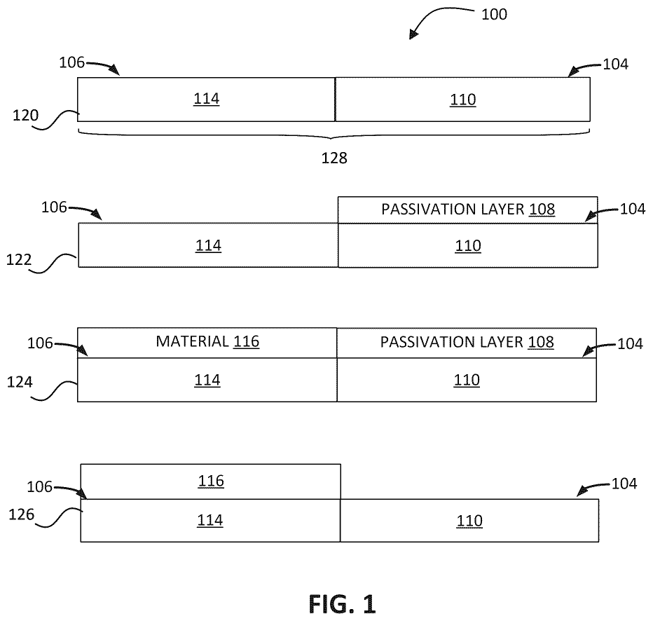

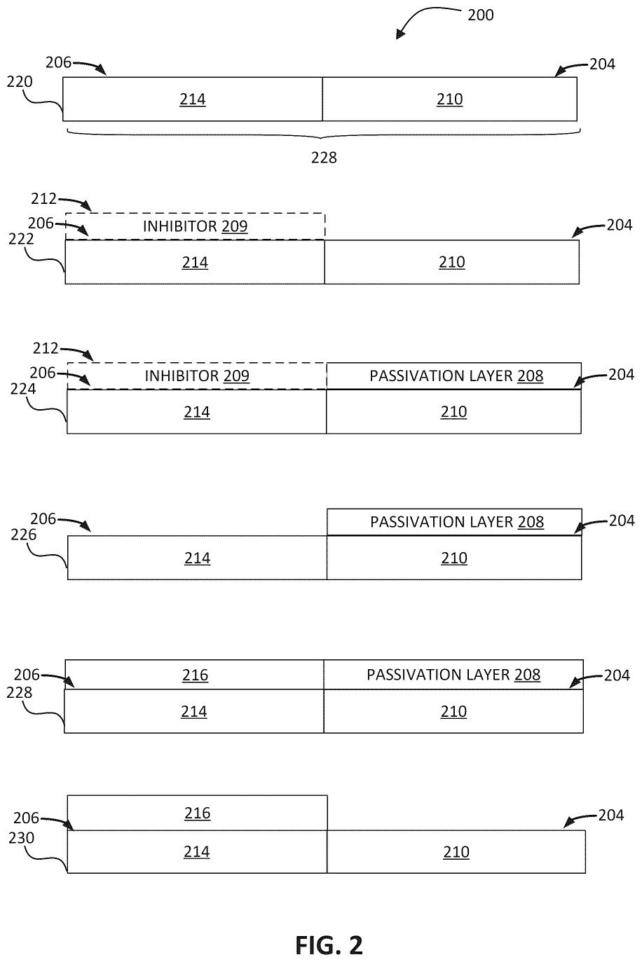

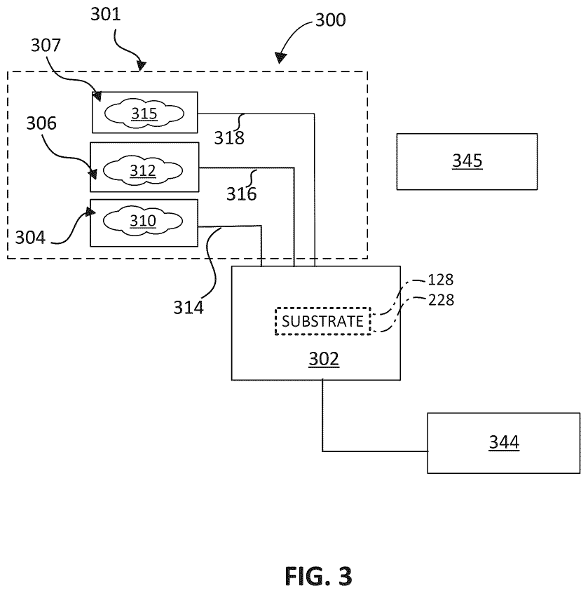

FIG. 1 schematically illustrates an example process 100 for selective passivation of a substrate 128 of a first surface 104 relative to a second surface 106 (or inhibitor surface 112), followed by selective deposition on the second surface 106 relative to the passivated first surface 104. The following description of process 100 is with reference to FIGS. 2 and 3.

In an example, process 100 starts at operation 120 wherein a substrate 128 having a first surface 104 and a second surface 106 is supported in a reaction chamber 302 (see FIG. 3). In the illustrated example, the first surface 104 comprises a first material 110. The first material 110 may be any of a variety of materials.

In some examples, first material 110 may be metallic and/or comprise a metal. Accordingly, first material 110 may comprise metal oxide, metal nitride, metal boride, elemental metal, a metallic surface, amorphous carbon, or a combination thereof. In some examples, first material 110 may comprise aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr) or vanadium (V), the like or a combination thereof. In some examples, first material 110 may comprise RuOx, NiOx, CoOx, NbOx, MoOx, WOx, NbBx, NbCx, WNCx, TaN, or TiN.

In some examples, first material 110 may be a dielectric. Accordingly, first material 110 may comprise SiCOx, SiOx, Si, high-k material, or low-k material, or the like or a combination thereof. In some examples, first material 110 may comprise zirconium oxide (ZrOx), hafnium oxide (HfOx), aluminum oxide (Al2O3), titanium nitride (TiN), titanium oxide (TiOx), aluminum nitride (AlN), or the like, or a combination thereof.

In the illustrated example, the second surface 106 comprises a second material 114. The second material 114 may comprise any of a variety of materials.

In some examples, second material 114 may comprise a dielectric. Accordingly, second material 114 may comprise SiCOx, SiOx, Si, high-k materials, or low-k materials, or the like or a combination thereof. In some examples, second material 114 may comprise dielectrics, such as zirconium oxide (ZrOx), hafnium oxide (HfOx), aluminum oxide (Al2O3), titanium nitride (TiN), titanium oxide (TiOx), aluminum nitride (AlN), or the like, or a combination thereof.

In some examples, second material 114 may be metallic and/or comprise a metal. In some examples, second material 114 may comprise metal oxide, metal nitride, metal boride, elemental metal, a metallic surface, amorphous carbon, or a combination thereof. In some examples, second material 114 may comprise aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr) or vanadium (V), the like, or a combination thereof. In some examples, second material 114 may comprise RuOx, NiOx, CoOx, NbOx, MoOx, WOx, NbBx, NbCx, WNCx, TaN, or TiN, or combinations thereof.

Process 100 may continue to operation 122 where selective deposition of a passivation layer 108 over first surface 104 may be performed.

In some examples, first material 110 and second material 114 of substrate 128 may be materially different thus exposed first surface 104 and second surface 106 may be materially different. For example, the first material 110 may be metallic and/or comprise a metal and second material 114 may comprise a dielectric, such as a low-k layer (typically a silicon oxide-based layer) or a silicon surface having native oxide (also a form of silicon oxide) formed thereover. Thus, first surface 104 may be metallic and/or comprise a metal and second surface 106 may comprise a dielectric, such as a low-k layer (typically a silicon oxide-based layer) or a silicon surface having native oxide (also a form of silicon oxide) formed thereover.

At operation 122, selective deposition of a passivation layer 108 over first surface 104 may be performed. Passivation layer 108 may be a polymer layer deposited selectively on the metallic surface of the first surface 104. Example methods for selectively depositing polymer layers by vapor deposition techniques are disclosed in U.S. Patent Ser. No. 10,373,820 issued Aug. 6, 2019, the entire disclosure of which is incorporated herein by references for all purposes. Further information and examples of selective deposition of polymer layers to serve as the passivation layer are provided below.

In some examples, the selectively deposited polymer is a polyimide. In some examples, the polymer deposited is a polyamide. Other examples of deposited polymers include dimers, trimers, polyurea layers, polythiophene polyurethanes, polythioureas, polyesters, polyimines, other polymeric forms or mixtures of the above materials. Vapor deposited organic materials include polyamic acid, which may be a precursor to polymer formation. The selectively deposited layer can be a mixture including polymer and polyamic acid, which for purposes of the present disclosure will be considered to be a polymer.

In an example, organic material deposited on the second surface 106 can be removed by an etch back process. In some examples, an etch process subsequent to selective deposition of the organic layer may remove deposited organic material from both the first surface 104 and the second surface 106 of the substrate. In some examples the etch process may be isotropic.

In an example, the etch process may remove the same amount, or thickness, of material from the first and second surfaces. That is, in some examples the etch rate of the organic material deposited on the first surface 104 may be substantially similar to the etch rate of the organic material deposited on the second surface 106. Due to the selective nature of the deposition processes described herein, the amount of organic material deposited on the second surface 106 of the substrate 128 is substantially less than the amount of material deposited on the first surface 104 of the substrate 128. Therefore, an etch process may completely or nearly completely remove deposited organic material from the second surface 106 of the substrate while deposited organic material may remain on the first surface 104 of the substrate 128.

At operation 124, selective deposition of a material layer 116 on second surface 106 (an inorganic dielectric surface in this example) relative to the passivation layer 108 on the first surface 104 may be performed. In an example, first surface 104 may be a conductive, metal, or metallic surface. In an example, material layer 116 can be a dielectric material, particularly a metal oxide such as zirconium oxide, hafnium oxide and/or titanium oxide. Example methods for selectively depositing such metal oxide layers by vapor deposition techniques, employing hydrophobic precursors to aid selectivity relative to organic passivation layers, are disclosed in U.S. Pat. No. 11,081,342 issued Aug. 3, 2021, the entire disclosure of which is incorporated herein by reference for all purposes. Further information and examples of selective deposition of metal oxide and other layers of interest are provided below.

In an example, material layer 116 material deposited on passivation layer 108 can be removed by an etch back process. Because the material layer 116 is deposited selectively on the second surface 106, any material layer 116 material left on passivation layer 108 will be thinner than material layer 116 formed on second surface 106. Accordingly, the etch back process can be controlled to remove all of the material over the passivation layer 108 without removing all of the material layer 116 from over the dielectric second surface 106. Repeatedly depositing selectively and etching back in this manner can result in an increasing thickness of the material comprising material layer 116 on second surface 106 with each cycle of deposition and etch. Repeatedly depositing selectively and etching back in this manner can also result in increased overall selectivity of the material on the dielectric, as each cycle of deposition and etch leaves a clean passivation layer 108 over which the material, deposited by the selective deposition of layer of interest 110, nucleates poorly.

Alternatively, any material layer 116 material can be removed during subsequent removal of the passivation layer, in a lift-off process. As is known in the art, a lift-off process removes an overlying material by undercutting with removal of an underlying material. Any material layer 116 material formed on the passivation layer 110 in a short selective deposition process tends to be noncontinuous, allowing access of the etchant to the underlying material to be removed. The lift-off etch need not fully remove the passivation layer 110 in order to remove all of the undesired material layer 116 material from the passivation layer 110 surface, such that either a direct etch or the lift-off method can be used to remove the material layer 116 material from the passivation layer 110 surface in a cyclical selective deposition and removal.

At operation 126, substrate 128 is shown after removal of the passivation layer 110 from the first surface 104. In some examples, the etch process may comprise exposing the substrate to a plasma. In some examples, the plasma may comprise oxygen atoms, oxygen radicals, oxygen plasma, or combinations thereof. In some examples, the plasma may comprise hydrogen atoms, hydrogen radicals, hydrogen plasma, or combinations thereof. In some examples, the plasma may also comprise noble gas species, for example Ar or He species. In some examples the plasma may consist essentially of noble gas species. In some instances, the plasma may comprise other species, for example nitrogen atoms, nitrogen radicals, nitrogen plasma, or combinations thereof. In some examples, the etch process may comprise exposing the substrate to an etchant comprising oxygen, for example 03. In some examples, the substrate may be exposed to an etchant at a temperature of between about 30° C. and about 500° C., preferably between about 100° C. and about 400° C. In some examples, the etchant may be supplied in one continuous pulse or may be supplied in multiple shorter pulses. Passivation layer 110 removal can be used to lift-off any remaining layer of interest 10 material from over the passivation layer, either in a complete removal of the passivation layer or in a partial removal of the passivation layer in a cyclical selective deposition and removal.

As noted above, in some examples, O₃ (e.g. O₃/N₂) can be used in the etch process for removal of the organic passivation layer. In some examples, the etch process may be performed at a substrate temperature of about 20° C. to about 500° C. In some examples, the etch process may be performed at a substrate temperature of about 50° C. to about 300° C. In some examples, the etch process may be performed at a substrate temperature of about 100° C. to about 250° C. In some examples, the etch process may be performed at a substrate temperature of about 125° C. to about 200 C. In some examples, the etch process may be performed at a rate of about 0.05 nm/min to about 50.0 nm/min. In some examples, the etch process may be performed at a rate of about 0.1 nm/min to about 5.0 nm/min. In some examples, the etch process may be performed at a rate of about 0.2 nm/min to about 2.5 nm/min. In some examples for single wafer or small batch (e.g., 5 wafers or less) processing, a low O₃ concentration etch process may be used, wherein the low O₃ concentration etch process is performed at 0.01 Torr to 200 Torr, more particularly about 0.1 Torr to 100 Torr (e.g., 2 Torr). Etchant pulsing can be between 0.01 sec and 20 seconds, particularly between 0.05 sec and 10 sec, even more particularly between 0.1 sec and 2 seconds (e.g., 0.5 sec pulse/0.5 sec purge of O3). O3 flow can range from 0.01 slm to 1 slm, more particularly from 0.01 slm to 0.250 slm. Inert (e.g., N₂) carrier gas flow of can range from 0.1 slm to 20 slm, more particularly from 0.5 slm to 5 slm (e.g., 1.2 slm). In some examples, a high O₃ concentration etch process may be used, wherein the high O₃ concentration etch process is performed at 1-100 Torr, more particularly 5-20 Torr (e.g., 9 Torr), with longer exposures per cycle. For example, O₃ exposure times can be between 0.1 sec and 20 s, more particularly between 0.5 sec and 5 seconds (e.g., 1 sec pulse/1 sec purge of O₃). O₃ flow for such high O₃ concentration processes can be between 0.1 slm and 2.0 slm, more particularly between 0.5 slm and 1.5 slm (e.g, 750 sccm), with an inert (e.g., N₂) dilution flow of 0.1 slm to 20 slm, more particularly 0.5 slm to 5 slm (e.g., 1.2 slm).

Additional treatments, such as heat or chemical treatment, can be conducted prior to, after or between the foregoing processes. For example, treatments may modify the surfaces or remove portions of the metal, silicon oxide, polymer passivation and metal oxide surfaces exposed at various stages of the process. In some examples the substrate may be pretreated or cleaned prior to or at the beginning of the selective deposition process. In some examples, the substrate may be subjected to a plasma cleaning process at prior to or at the beginning of the selective deposition process. In some examples, a plasma cleaning process may not include ion bombardment, or may include relatively small amounts of ion bombardment. For example, in some examples the substrate surface may be exposed to plasma, radicals, excited species, and/or atomic species prior to or at the beginning of the selective deposition process. In some examples, the substrate surface may be exposed to hydrogen plasma, radicals, or atomic species prior to or at the beginning of the selective deposition process. In some examples, a pretreatment or cleaning process may be carried out in the same reaction chamber as a selective deposition process, however in some examples a pretreatment or cleaning process may be carried out in a separate reaction chamber.

In certain examples, the material differences between the two surfaces are such that vapor deposition methods can selectively deposit the organic passivation layer on the first surface relative to the second surface. In some embodiments, cyclical vapor deposition is used, for example, cyclical CVD or atomic layer deposition (ALD) processes are used. In some embodiments, selectivity for the organic passivation layer can be achieved without passivation/blocking agents on the surface to receive less of the organic layer; and/or without catalytic agents on the surface to receive more of the organic layer. For example, in embodiments where the first surface is metallic and the second surface is dielectric, polymers can be selectively deposited directly on metallic surfaces relative to inorganic dielectric surfaces. In other embodiments, where the first surface is dielectric and the second surface is metallic, the second surface may be first treated to inhibit polymer deposition thereover. For example, an inhibitor such as a passivation blocking self-assembled monolayer (SAM) and/or alkylsilane or other inhibiting species (as will be described in further detail below) can be first formed over a metallic (or other appropriate material) surface, facilitating selective deposition of a polymer passivation layer on a dielectric surface, such as an inorganic dielectric surface, relative to a SAM-covered or other inhibitor-covered second metallic surface. Example methods for selective deposition of SAMs to serve as passivation blocking layers (“inhibitors”) are disclosed in U.S. patent application U.S. Ser. No. 17/388,773 filed Jul. 29, 2021, the entire disclosure of which is incorporated herein by reference for all purposes. Further information and examples of selective deposition of SAMs to serve as the passivation blocking layers are provided below. Example methods for selectively depositing alkylsilane passivation blocking layers (“inhibitors”) are disclosed in U.S. provisional patent application U.S. 63/583,732 filed Sep. 19, 2023, the entire disclosure of which is incorporated herein by reference for all purposes. Further information and examples of selective deposition of alkylsilanes to serve as the passivation blocking layers are provided below.

After selective deposition of the organic passivation is completed, further selective deposition of materials of interest, such as metal oxide or metal layers, can be conducted on the non-passivated second surface relative to the passivated first surface.

FIG. 2 illustrates schematically a second embodiment for selective passivation process 200 of a first surface 204 relative to a second surface 206, followed by selective deposition on the second surface 206 relative to the passivated first surface 204. In the illustrated embodiment, the first material 210 and first surface 204 comprise an inorganic dielectric material; the second material 210 is metallic and second surface 206 comprises a metallic surface; and the material of interest 216 deposited on the second surface comprises a dielectric material or a metal. The following description of process 100 is with reference to FIGS. 2 and 3.

FIG. 2 illustrates a substrate similar to that of FIG. 1, having materially different surfaces. For this embodiment, however, the surfaces are described with reversed terminology. In particular, the second surface 206 can comprise or be defined by a metallic material, metal oxide, metal nitride, metal boride, elemental metal, a metallic surface, amorphous carbon, or a combination thereof. In some examples, second surface 206 may be aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr) or vanadium (V), the like, or a combination thereof. In other examples, second surface 206 may be RuOx, NiOx, CoOx, NbOx, MoOx, WOx, NbBx, NbCx, WNCx, TaN, or TiN, or combinations thereof.

In an example, first material 210 and/or first surface 204 can comprise an inorganic dielectric, such as a low-k layer (typically a silicon oxide-based layer) or a silicon surface having native oxide (also a form of silicon oxide) formed thereover, for example, first material 210 and/or first surface 204 can comprise SiCOx, SiOx, SiO2, SiN, SiC, SiOC, SiON, SiOCN, SiGe, Si, high-k material, low-k material, or the like or a combination thereof. In some examples, first material 210 and/or first surface 204 may comprise zirconium oxide (ZrOx), hafnium oxide (HfOx), aluminum oxide (Al2O3), titanium nitride (TiN), titanium oxide (TiOx), aluminum nitride (AlN), or the like, or a combination thereof.

The following description of process 200 is with reference to FIGS. 2 and 3. In an example, process 200 starts at operation 220 wherein a substrate 228 having a first surface 204 and a second surface 206 is supported in a reaction chamber 302 (see FIG. 3).

Process 200 may continue to operation 222 where selective deposition of a “passivation blocking layer” (referred to interchangeably herein as “inhibitor”) 209 over second surface 206 may be performed. A passivation blocking layer is formed over the second surface. Note that the term “blocking” is not meant to imply that the subsequent selective deposition of a passivation layer is completely blocked by the passivation blocking layer. Rather, the passivation blocking layer over the second surface need only inhibit the deposition of the passivation layer to have a lower growth rate relative to the growth rate over the first surface.

In one embodiment, the passivation blocking layer or inhibitor 209 may comprise a self-assembled monolayer (SAM). Preferably SAM can be selectively formed over the second (metallic) surface 206 without forming on the first (dielectric) surface 204. In some examples, sulfur-containing SAM has been found particularly effective to minimize deposition of the passivation layer thereover. An example sulfur-containing SAM, employing vapor-delivered 1-dodecanaethiol (CH3 (CH2)11SH) may be used in operation 222.

In some examples, the inhibitor 209 may comprise an alkylsilane such as, bis(tert-pentoxy)methylsilanol, tris(tert-pentoxy) silanol, tris(tert-butoxy) silanol (TBS), tris(isopropoxy) silanol (TIS), or tris(tert-pentoxy) silanol (TPS), bis(tert-pentoxy)methylsilanol, bis(tert-butoxy)methylsilanol or bis(tert-pentoxy)ethylsilanol. Contacting the substrate 228 with the inhibitor reactant may be performed at a temperature of below 400° C., such as at a temperature from about 100° C. to about 400° C., for example at a temperature of about 200° C. or at a temperature of about 250° C. or at a temperature of about 300° C. or at a temperature of about 320° C. or at a temperature of about 350° C.

In another example, the inhibitor 209 may be represented by formula (1):

SiaRx(OH)y(OR′)z

where: a is 1, 2 or 3, x is 1, 2 or 3, y is 0, 1 or 2, and z is 1, 2 or 3, with the proviso that x+y+z=a +2, and each R and R′ is independently selected from linear and branched C1 to C8 alkyls.

In an example, R′ of Formula 1 is selected from, isopropyl, sec-butyl, tert-butyl, 1,1-dimethylpropyl, 2,2-dimethylpropyl, 1-methylbutyl, 3-methylbutyl, 3-pentyl, 1,2-dimethylpropyl and 2-methylbutyl. In an example, R is methyl or ethyl.

In an example, Formula 1 is selected from a group consisting of Si(OH) CH3 (OCH(CH3)2)2, Si(OH)2CH3 (OCH(CH3)2), Si(OH)(CH3)2 (OCH(CH3)2), Si(OH) CH3 (OC(CH3)3)2, Si(OH)2CH3 (OC(CH3)3), Si(OH)(CH3)2 (OC(CH3)3), Si(OH) CH2CH3 (OC(CH3)3)2, Si(OH)(CH2CH3)2 (OC(CH3)3), Si(OH) CH3 (OC [(CH3)2 (CH2CH3)])2, Si(OH)2CH3 [(CH3)2 (CH2CH3)], Si(OH)(CH3)2 [(CH3)2 (CH2CH3)], SiCH3 (OCH(CH3)2)3, Si(CH3)2 (OCH(CH3)2)2, Si(CH3)3 (OCH(CH3)2), SiCH3 (OC(CH3)3)3, Si(CH3)2 (OC(CH3)3)2, Si(CH3)3 (OC(CH3)3), Si(CH2CH3)(OC(CH3)3)3, Si(CH2CH3)2 (OC(CH3)3)2, Si(CH2CH3)3 (OC(CH3)3), SiCH3 (OC [(CH3)2 (CH2CH3)])3, Si(CH3)2 [(CH3)2 (CH2CH3)]2 and Si(CH3)3 [(CH3)2 (CH2CH3).

In an example, Formula 1 is selected from Si(OH)2R(OR′), Si(OH) R2 (OR′), Si(OH) R(OR′)2, R(OR′)(OH) Si—Si(OH) R(OR′), Si2 (OH)2R2 (OR′)2, Si2 (OH) R2 (OR′)2, SiR(OR′)3, SiR2 (OR′)2, SiR3 (OR′), R2 (OR′) Si—SiR2 (OR′), R(OR′)2Si—SiR(OR′)2.

In some embodiments, the first surface 204 is a high-k surface, and the second surface 206 is a silicon-containing dielectric surface, such as a silicon oxide surface or a low-k surface, e.g. SiOC surface.

At operation 224, passivation layer 208 is formed over the first surface 204, in this case the inorganic dielectric layer, relative to the passivation blocking layer 209 over the second surface 206. As noted in U.S. Pat. No. 10,373,820, issued Aug. 6, 2019, the entire disclosure of which is incorporated herein by reference for all purposes, deposition processes described therein are capable of depositing polymer on inorganic dielectrics, and can even deposit selectively (i.e., at differential deposition rates) over different types of silicon oxide. In the present embodiment, SAMs, alkylsilane, or other appropriate inhibitors block polymer deposition thereover, such that polymer can selectively form over the first surface and can serve as a passivation layer against a subsequent deposition. Moreover, passivation layer 208 may comprise any passivation material described herein above or below, such as any polyimides or polyamides formed from anhydrides, including thioanhydrides (e.g., pyromellitic dithioanhydride).

At operation 226, inhibitor 209 is removed from over the second surface 206 of substrate 228. For example, SAM material can be removed by heat treatment at temperatures lower than those that would remove a polymer layer like polyimide. Accordingly, a passivation layer is left selectively over the first surface 204, while the second surface 206 is exposed.

At operation 228, material layer 216 is deposited on second surface 206 relative to the passivation layer 208 over first surface 204. As noted with respect to the first embodiment and described in US Pat. No. U.S. Pat. No. 11,081,342, issued Aug. 3, 2021, which is incorporated herein by reference for all purposes, metal oxides can be selectively deposited using vapor deposition techniques and hydrophobic precursors to aid selectivity relative to organic passivation layers, on a number of different surfaces. Further information and examples of selective deposition of metal oxide and other layers of interest are provided below.

Alternatively, material layer 216 may be a metal layer. U.S. Pat. No. 8,956,971, issued Feb. 17, 2015 and U.S. Pat. No. 9,112,003, issued Aug. 18, 2015, the entire disclosures of which are incorporated herein by reference for all purposes, teaches processes for selective deposition of metallic materials on metallic surfaces, relative to other material surfaces, including organic surfaces.

Alternatively, material layer 216 may be a dielectric layer. U.S. provisional patent application U.S. 63/583,732 filed Sep. 19, 2023, the entire disclosure of which is incorporated herein by reference for all purposes teaches processes for selective deposition of dielectric materials on metallic surfaces, relative to other material surfaces, including organic surfaces. Material layer 216 may be any other appropriate material known to those of skill in the art.

At operation 230, passivation layer 208 may be removed from surface 204 of substrate 228 leaving a selectively formed dielectric, metal, metal oxide, or other appropriate material layer 216 on metal. The passivation layer 208 can be removed as described above with respect to the first embodiment, such as by 03 etching.

FIG. 3 illustrates a deposition assembly 300 according to the current disclosure in a schematic manner. Deposition assembly 300 can be used to perform a method as described herein and/or to selectively deposit organic material as described herein. In yet another aspect, semiconductor processing assembly 300 may be configured for selectively depositing an inhibitor material on a first surface of a substrate.

In the illustrated example, deposition assembly 300 includes one or more reaction chambers 302, a precursor injector system 301, a first precursor vessel 304, a second precursor vessel 306, a third precursor vessel 307, an exhaust source 344, and a controller 345. The deposition assembly 300 may comprise one or more additional gas sources (not shown), such as an inert gas source, a carrier gas source and/or a purge gas source. Reaction chamber 302 can include any suitable reaction chamber, such as an ALD or CVD reaction chamber as described herein.

The first precursor vessel 304 can include a vessel and one or more first precursors as described herein-alone or mixed with one or more carrier (e.g., inert) gases. A second precursor vessel 306 can include a vessel and one or more second precursors as described herein-alone or mixed with one or more carrier gases. A third precursor vessel 307 can include a vessel and one or more inhibitors as described herein-alone or mixed with one or more carrier gases. Although illustrated with three source vessels 304, 306, and 307 a deposition assembly 300 can include any suitable number of source vessels. Source vessels 304, 306, and 307 can be coupled to reaction chamber 302 via respective lines 314, 316 and 318, which can each include flow controllers, valves, heaters, and the like. In some examples, the first precursor 310 in the first precursor vessel 304, the second precursor 312 in the second precursor vessel 306 and the inhibitor 315 in the third precursor vessel 307 may be heated.

Exhaust source 344 can include one or more vacuum pumps. Controller 345 includes electronic circuitry and software to selectively operate valves, manifolds, heaters, pumps and other components included in the deposition assembly 300. Such circuitry and components operate to introduce precursors, reactants and purge gases from the respective sources. Controller 345 can control timing of gas pulse sequences, temperature of the substrate and/or reaction chamber 302, pressure within the reaction chamber 302, and various other operations to provide proper operation of the deposition assembly 300. Controller 345 can include control software to electrically or pneumatically control valves to control flow of precursors, reactants and purge gases into and out of the reaction chamber 302. Controller 345 can include modules such as a software or hardware component, which performs certain tasks. A module may be configured to reside on the addressable storage medium of the control system and be configured to execute one or more processes.

Other configurations of deposition assembly 300 are possible, including different numbers and kinds of precursor and reactant sources. Further, it will be appreciated that there are many arrangements of valves, conduits, precursor sources, and auxiliary reactant sources that may be used to accomplish the goal of selectively and in coordinated manner feeding gases into reaction chamber 302. Further, as a schematic representation of a deposition assembly, many components have been omitted for simplicity of illustration, and such components may include, for example, various valves, manifolds, purifiers, heaters, containers, vents, and/or bypasses.

During operation of deposition assembly 300, substrates, such as semiconductor wafers (e.g., optional substrate 128 or 228), are transferred from, e.g., a substrate handling system to reaction chamber 302. Once substrate(s) are transferred to reaction chamber 302, one or more gases from gas sources, such as precursors, reactants, carrier gases, and/or purge gases, are introduced into reaction chamber 302.

In an example, the first precursor 310 may comprise a diamine, triamine, tetraamine and/or cyclic compound comprising at least two primary amine groups, as described in greater detail herein. In an example, second precursor 312, may comprise an anhydride, such as furan-2,5-dione (maleic acid anhydride), dianhydride, (e.g., pyromellitic dianhydride (PMDA)) and/or a dianhydride comprising at least one thioanhydride group (e.g., 1,2,4,5-tetrathio-cyclic 1,2:4,5-bis(anhydrosulfide)1,2,4,5-benzenetetracarboxylic acid (pyromellitic dithioanhydride (PMDTA))) as described in greater detail herein.

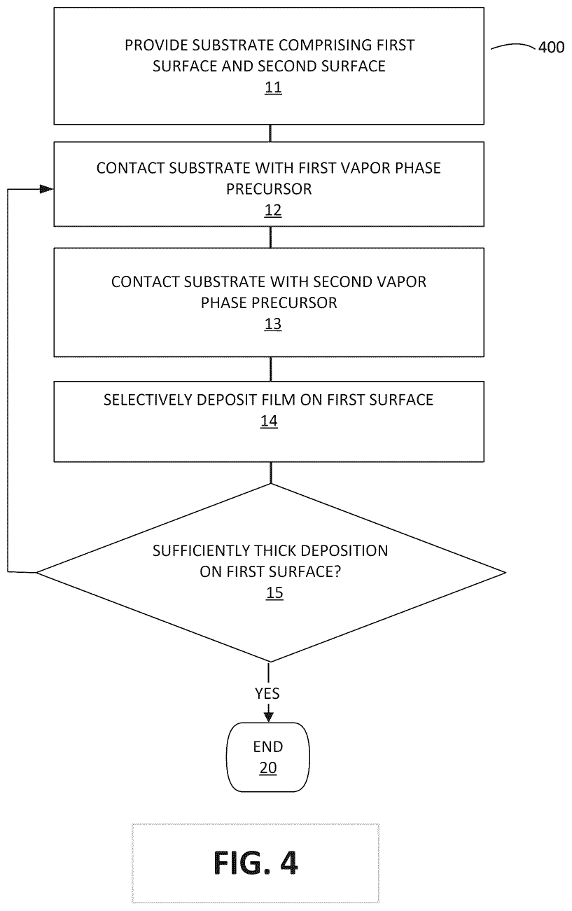

FIG. 4 illustrates an example process 400 for selective passivation of a substrate comprising a first surface and a second surface. In an example, at block 11 the substrate is provided. The first and second surfaces may have different material properties. In some examples the first surface may be a conductive surface, for example a metal or metallic surface, and the second surface may be a dielectric surface. In some embodiments the first surface may be a dielectric surface and the second surface may be a second, different dielectric surface. In some embodiments the first and second surfaces may have the same basic composition but may have different material properties due to different manners of formation (e.g., thermal oxide, deposited oxide, native oxide).

In some embodiments the first precursor may be vaporized at a first temperature to form the first vapor phase precursor. In some embodiments the first precursor vapor is transported to the substrate through a gas line at a second temperature. In some embodiments the second transportation temperature is higher than the first vaporization temperature. In some embodiments the substrate is contacted with a first vapor phase precursor, or reactant, at block 12 for a first exposure period. In some embodiments the substrate may be contacted with the first vapor phase precursor at a third temperature that is higher than the first temperature.

In some embodiments the first precursor exposure period is from about 0.01 seconds to about 60 seconds, about 0.05 seconds to about 30 seconds, about 0.1 seconds to about 10 seconds or about 0.2 seconds to about 5 seconds. The optimum exposure period can be readily determined by the skilled artisan based on the particular circumstances. In some embodiments where batch reactors may be used, exposure periods of greater than 60 seconds may be employed.

In some embodiments the substrate is contacted with a second vapor phase precursor, or reactant, at block 13 for a second exposure period. In some embodiments the second precursor may be vaporized at a fourth temperature to form the second vapor phase precursor. In some embodiments the second precursor vapor is transported to the substrate through a gas line at a second temperature. In some embodiments the fifth transportation temperature is higher than the first vaporization temperature. In some embodiments the substrate may be contacted with the second vapor phase precursor at a sixth temperature that is higher than the fourth temperature. In some embodiments the sixth temperature may be substantially the same as the third temperature at which the first vapor phase precursor contacts the substrate.

In some embodiments the second precursor exposure period is from about 0.01 seconds to about 60 seconds, about 0.05 seconds to about 30 seconds, about 0.1 seconds to about 10 seconds or about 0.2 seconds to about 5 seconds. The optimum exposure period can be readily determined by the skilled artisan based on the particular circumstances. In some embodiments where batch reactors may be used, exposure periods of greater than 60 seconds may be employed.

In block 14 an organic film is selectively deposited on the first surface relative to the second surface. The skilled artisan will appreciate that selective deposition of an organic film is the result of the above-described contacting actions, 12-13, rather than a separate action. In some embodiments, the above-described contacting actions, blocks 12-13, may be considered a deposition cycle. In some embodiments a deposition cycle may repeated until an organic film of a desired thickness is selectively deposited. Such a selective deposition cycle can be repeated until a film of sufficient thickness is left on the substrate (decision block 15) and the deposition is ended (block 16). The selective deposition cycle can include additional acts, need not be in the same sequence nor identically performed in each repetition, and can be readily extended to more complex vapor deposition techniques. For example, a selective deposition cycle can include additional reactant supply processes, such as the supply and removal (relative to the substrate) of additional reactants in each cycle or in selected cycles. Though not shown, the process may additionally comprise use of inhibitor (e.g., as described above with respect to FIG. 2), treating the deposited film to form a polymer (for example, UV treatment, annealing, etc.).

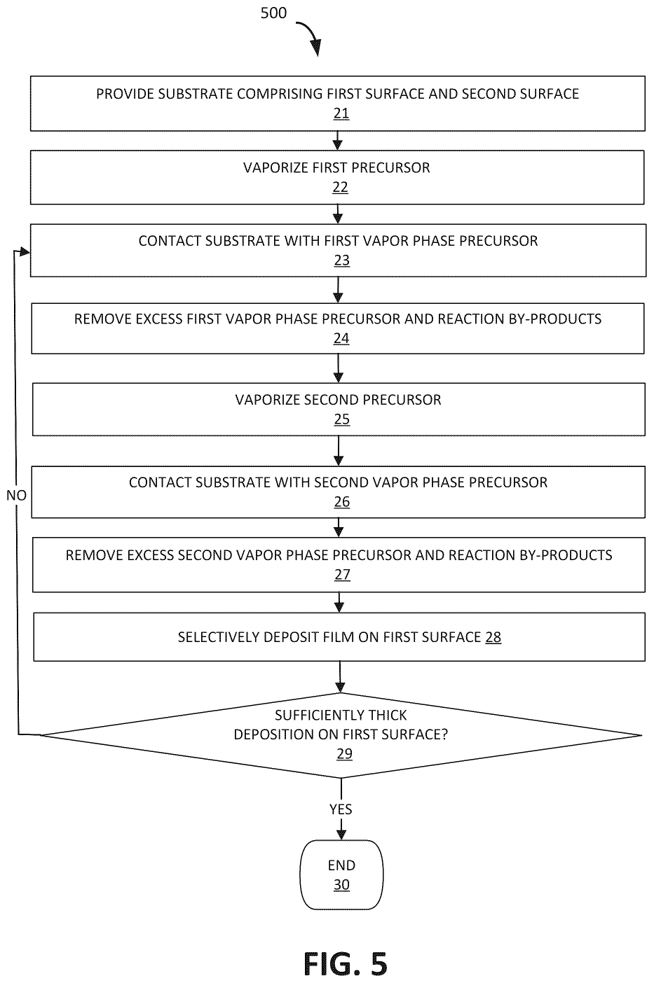

FIG. 5 illustrates an example process 500 for selective passivation of a substrate comprising a first surface and a second surface. In an example, a substrate comprising a first surface and a second surface is provided at block 21. The first and second surfaces may have different material properties. In some embodiments the first surface may be a conductive surface, for example a metal or metallic surface, and the second surface may be a dielectric surface. In some embodiments the first surface may be a dielectric surface and the second surface may be a second, different dielectric surface. In some embodiments, the first surface may be a dielectric surface and the second surface may comprise a second, different dielectric surface. In some examples, the first surface may be a dielectric (or other material) surface and the second surface may comprise a passivation blocking or inhibitor layer, such as a self-assembled monolayer (SAM) or alkylsilane or other inhibiting species (e.g., as described with respect to FIG. 2). In some embodiments, the first and second surfaces may have the same basic composition but may have different material properties due to different manners of formation (e.g., thermal oxide, deposited oxide, native oxide).

In some embodiments, a sequential deposition method for selective vapor deposition of an organic film comprises vaporizing a first precursor at a first temperature to form a first precursor vapor at block 22. In some embodiments the first precursor vapor is transported to the substrate through a gas line at a second temperature. In some embodiments the second transportation temperature is higher than the first vaporization temperature. In some embodiments the substrate is contacted with the vapor phase first precursor for a first exposure period at block 23. In some embodiments, the first precursor, or species thereof, chemically adsorbs on the substrate in a self-saturating or self-limiting fashion. The gas line can be any conduit that transports the first precursor vapor from the source to the substrate. In some embodiments, the substrate may be exposed to the first precursor vapor at a third temperature that is higher than the first temperature.

In some embodiments the first precursor exposure period is from about 0.01 seconds to about 60 seconds, about 0.05 seconds to about 30 seconds, about 0.1 seconds to about 10 seconds or about 0.2 seconds to about 5 seconds. The optimum exposure period can be readily determined by the skilled artisan based on the particular circumstances. In some embodiments where batch reactors may be used, exposure periods of greater than 60 seconds may be employed.

Excess of the first precursor vapor (and any volatile reaction by-products) may then be removed from contact with the substrate at block 24. Such removal can be accomplished by, for example, purging, pump down, moving the substrate away from a chamber or zone in which it is exposed to the first precursor, or combinations thereof. In some embodiments a first precursor removal period, for example a purge period, is from about 0.01 seconds to about 60 seconds, about 0.05 seconds to about 30 seconds, about 0.1 seconds to about 10 seconds or about 0.2 seconds to about 5 seconds. The optimum removal period can be readily determined by the skilled artisan based on the particular circumstances. In some embodiments where batch reactors may be used, removal periods of greater than 60 seconds may be employed.

In some embodiments the second precursor may be vaporized at a fourth temperature to form the second vapor phase precursor at block 25. In some embodiments the second precursor vapor is transported to the substrate through a gas line at a second temperature. In some embodiments the fifth transportation temperature is higher than the first vaporization temperature. In some embodiments the substrate may be contacted with the second vapor phase precursor at a sixth temperature that is higher than the fourth temperature. In some embodiments the sixth temperature may be substantially the same as the third temperature at which the first vapor phase precursor contacts the substrate. In some embodiments the substrate may be exposed to a second precursor vapor for a second exposure period at block 26. In some embodiments, the second precursor may react with the adsorbed species of the first precursor on the substrate.

In some embodiments the first precursor exposure period is from about 0.01 seconds to about 60 seconds, about 0.05 seconds to about 30 seconds, about 0.1 seconds to about 10 seconds or about 0.2 seconds to about 5 seconds. The optimum exposure period can be readily determined by the skilled artisan based on the particular circumstances. In some embodiments where batch reactors may be used, exposure periods of greater than 60 seconds may be employed.

In some embodiments excess of the second precursor vapor (and any volatile reaction by-product) is removed from contact with the substrate at block 27, such that the first precursor vapor and the second precursor vapor do not mix. In some embodiments the vapor deposition process of the organic film does not employ plasma and/or radicals, and can be considered a thermal vapor deposition process. In some embodiments a second precursor removal period, for example a purge period, is from about 0.01 seconds to about 60 seconds, about 0.05 seconds to about 30 seconds, about 0.1 seconds to about 10 seconds or about 0.2 seconds to about 5 seconds. The optimum removal period can be readily determined by the skilled artisan based on the particular circumstances. In some embodiments where batch reactors may be used, removal periods of greater than 60 seconds may be employed.

In block 28 an organic film is selectively deposited on the first surface relative to the second surface. The skilled artisan will appreciate that selective deposition of an organic film is the result of the above-described contacting actions rather than a separate action. The organic film may comprise a variety of films including but not limited to polymers such as polyimide films, polyamide films, polyurea films, polyurethane films, polythiophene films, and more. In some embodiments, the above-described contacting and removing (and/or halting supply) actions, blocks 23-27, may be considered a deposition cycle. In some embodiments a deposition cycle may be repeated until an organic film of a desired thickness is selectively deposited. Such a selective deposition cycle can be repeated (block 29) until a film of sufficient thickness is left on the substrate and the deposition is ended (block 30). The selective deposition cycle can include additional acts, need not be in the same sequence nor identically performed in each repetition, and can be readily extended to more complex vapor deposition techniques. For example, a selective deposition cycle can include additional reactant supply processes, such as the supply and removal of additional reactants in each cycle or in selected cycles. Though not shown, the process may additionally comprise treating the deposited film to form a polymer (for example, UV treatment, annealing, etc.).

Various reactants can be used for the above-described processes. For example, the first precursor or reactant is an organic reactant such as a diamine, (e.g., 1,6-diamnohexane (DAH)), a triamine (e.g., tris(aminoethyl)methylsilane), a tetraamine (e.g., 2,2-bis(aminomethyl)-1,3-propanediamine) and/or a cyclic compound comprising at least two primary amine groups. In some examples, the second precursor or precursor is also an organic reactant capable of reacting with adsorbed species of the first precursor under the deposition conditions. For example, the second precursor can be an anhydride, such as furan-2,5-dione (maleic acid anhydride), a dianhydride (e.g., pyromellitic dianhydride (PMDA) and/or pyromellitic dithioanhydride (PMDTA)), or any other species with two reactive groups which will react with the first precursor.

In some examples the substrate is contacted with the first precursor prior to being contacted with the second precursor. However, in some examples the substrate may be contacted with the second precursor prior to being contacted with the first precursor.

Although the above described processes begin with contacting the substrate with the first vapor phase precursor, in other examples a process may begin with contacting the substrate with the second vapor phase precursor. It will be understood by the skilled artisan that contacted the substrate with the first precursor and second precursor are interchangeable in the processes described herein.

In some examples, different reactants can be used to tune the film properties. For example, a polyimide film could be deposited using 4,4′-oxydianiline or 1,4-diaminobenzene instead of 1,6-diaminohexane to get a more rigid structure with more aromaticity and increased dry etch resistance.

In some examples the reactants do not contain metal atoms. In some examples the reactants do not contain semimetal atoms. In some examples one of the reactants comprises metal or semimetal atoms. In some examples the reactants contain carbon and hydrogen and one or more of the following elements: N, O, S, P or a halide, such as C1 or F. In some examples the first precursor may comprise, for example, adipoyl chloride (AC).

Deposition conditions can differ depending upon the selected reactants and can be optimized upon selection. In some examples the reaction temperature can be selected from the range of about 80° C. to about 250° C. In some examples, for example where the selectively deposited organic film comprises polyimide, the reaction temperature can be selected from the range of about 170° C. to about 210° C. In some examples, for example where the selectively deposited organic film comprises polyamide, the reaction temperature can be selected from a range of about 80° C. to about 150° C. In some examples where the selectively deposited organic film comprises polyimide the reaction temperature may be greater than about 160° C., 180° C., 190° C., 200° C., or 210° C. In some examples where the selectively deposited organic film comprises polyamide the reaction temperature may be greater than about 80° C., 90° C., 100° C., 110° C., 120° C., 130° C., 140° C., or 150° C.

In some examples the reaction chamber pressure may be from about 1 mTorr to about 1000 Torr.

For example, for sequential deposition of polyimide using PMDTA and DAH in a single wafer deposition tool, substrate temperatures can be selected from the range of about 150° C. to about 250° C., or from about 170° C. to about 225° C., and pressures can be selected from the range of about 1 mTorr to about 760 Torr, more particularly between about 100 mTorr to about 100 Torr.

In some examples the selectively deposited or formed organic film does not contain metal atoms. In some examples the selectively deposited or formed organic film does not contain semimetal atoms. In some examples the selectively deposited or formed organic film contains metal or semimetal atoms. In some examples the selectively deposited or formed organic film contains carbon and hydrogen and one or more of the following elements: N, O, S, or P.

Examples of suitable reactors that may be used in the selective deposition processes described herein include commercially available ALD equipment such as the F-120® reactor, Pulsar® reactor, such as a Pulsar 3000® or Pulsar 2000®, and Advance® 400 Series reactor, available from ASM America, Inc. of Phoenix, Ariz. and ASM Europe B.V., Almere, Netherlands. In addition to these ALD reactors, many other kinds of reactors capable growth of organic thin films, including CVD reactors, VDP reactors, and MLD reactors can be employed.

In some examples a suitable reactor may be a batch reactor and may contain two or more substrates. In some examples the substrate may comprise, for example, wafers. In some examples a suitable reactor may be a batch reactor that may contain two or more, five or more, 10 or more, 25 or more, 50 or more, or 100 or more substrates. In some examples the substrate may comprise wafers, for example, semiconductor or silicon wafers. In some examples the substrates may have diameters of 100 mm or more, 200 mm or more, or 300 mm or more. In some instances, substrates having diameters of 450 mm or more may be desirable.

In some examples the first surface (e.g., metallic surface) of a substrate onto which an organic film is to be selectively deposited may comprise a structure on a semiconductor substrate or integrated circuit workpiece. In some examples the first surface of the substrate may comprise one or more metal lines or dots. For example, the first surface of the substrate may comprise a W, Co, or Cu line while the second surface may comprise a silicon oxide-based material. That is, in some examples the substrate may comprise at least a first portion of the first metallic surface and a second portion of the first metallic surface, wherein the first and second portions of the first metallic surface are separated on the substrate by the second dielectric surface.

In some examples, the selectivity of the selective deposition processes described herein may change based on the dimensions or pitch of the portions of the first surface onto which the organic film is selectively deposited. In some examples the selectivity of the selective deposition processes described herein may increase as the pitch of the features comprising first surface increases. Increased pitch is used herein as conventional in the semiconductor industry to mean greater number of features in a given dimension, or greater density and closer spacing between features.

In some examples a selective deposition process can achieve a desired selectivity on a substrate wherein the periodicity of features comprising the first surface is less than about 1 micron, less than about 500 nm, less than about 250 nm, or less than about 100 nm. In some examples the periodicity of features comprising the first surface is less than 40 nm, or even less than 20 nm. As used herein, periodicity refers to the distance between the two nearest repeated structures, materials, or surfaces on a substrate. In some examples the selectivity of a selective deposition process may depend on the distance between a first portion of the substrate comprising a first surface and a second portion of the substrate comprising a first surface, such as the aforementioned periodicity for repeating patterns on a substrate. In some examples the selectivity of the selective deposition processes described herein may increase as the distance between the portions of the first material decreases.

In some examples a selective deposition process can achieve a desired selectivity on a substrate comprising a first portion of the first surface separated by a distance from a second portion of the first surface. In some examples the desired selectivity may be achieved when the distance between the first and second portions of the first surface is less than about 1 micron, less than about 500 nm, less than about 250 nm, or less than about 100 nm.

In some examples the selectivity of a selective deposition process may be related to the number of growth, or deposition cycles performed in the selective deposition process. In some examples the selectivity for a selective deposition process may increase with the number of deposition cycles. For example, the selectivity of a selective deposition process comprising 250 of deposition cycles may be less than the selectivity of a selective deposition process comprising 1000 deposition cycles where the conditions for the deposition cycles in each process are substantially the same. This is surprising, given that typical selective vapor deposition processes tend to lose selectivity with greater thickness or deposition duration.

In some examples an increase in the number of deposition cycles in a selective deposition process may result in a corresponding increase in the selectivity of the process. For example, in some examples doubling the number of deposition cycles may result in selective deposition process which is twice as selective.

Although generally a deposition or reaction temperature for the selective deposition processes described herein is greater than or equal to the vaporization temperatures of the first and second precursors, in some other examples the reaction temperature may be lower than one or both of the reactant vaporization temperatures.

Various reactants can be used to deposit polyamide or polyimide films according to the processes described herein. For example, in some examples the first precursor or reactant is an amine, for example a diamine. In some examples, the first precursor can be a diamine (e.g., 1,6-diamnohexane (DAH)), a triamine (e.g., tris(aminoethyl)methylsilane), a tetraamine (e.g., 2,2-bis(aminomethyl)-1,3-propanediamine) and/or a cyclic compound comprising at least two primary amine groups. In some examples, the substrate is contacted with the first precursor before it is contacted with the second precursor. Thus, in some examples the substrate may be contacted with an amine, such as a diamine, before it is contacted with a second precursor.

In some examples, the second precursor or precursor is also an organic reactant capable of reacting with adsorbed species of the first precursor under the deposition conditions. For example, in some examples, the second precursor or reactant is an organic reactant such as an anhydride, such as furan-2,5-dione (maleic acid anhydride), a dianhydride (e.g., pyromellitic dianhydride (PMDA) and/or pyromellitic dithioanhydride (PMDTA)), or any other species with two reactive groups which will react with the first precursor.

In some examples the reactants do not contain metal atoms. In some examples the reactants do not contain semimetal atoms. In some examples one of the reactants comprises metal or semimetal atoms. In some examples the reactants contain carbon and hydrogen and one or more of the following elements: N, O, S, P or a halide, such as C1 or F. In some examples the first precursor may comprise, for example, adipoyl chloride (AC).

### First Precursor

In some examples, a first precursor for use in the selective deposition processes described herein may have the general formula: R₁ (NH₂)₂ (1)

Wherein R1 may be an aliphatic carbon chain comprising 1-5 carbon atoms, 2-5 carbon atoms, 2-4 carbon atoms, 5 or fewer carbon atoms, 4 or fewer carbon atoms, 3 or fewer carbon atoms, or 2 carbon atoms. In some examples the bonds between carbon atoms in the reactant or precursor may be single bonds, double bonds, triple bonds, or some combination thereof. Thus, in some examples a reactant may comprise two amino groups. In some examples the amino groups of a reactant may occupy one or both terminal positions on an aliphatic carbon chain. However, in some examples the amino groups of a reactant may not occupy either terminal position on an aliphatic carbon chain. In some examples a reactant may comprise a diamine. In some examples a reactant may comprise an organic precursor selected from the group of 1,2-diaminoethane (1), 1,3-diaminopropane (1), 1,4-diaminobutane (1), 1,5-diaminopentane (1), 1,2-diaminopropane (1), 2,3-butanediamine, 2,2-dimethyl-1,3-propanediamine (1).

In some examples, a reactant being vaporized can be also a diamine, such as 1,4-diaminobenzene, decane-1,10-diamine, 4-nitrobenzene-1,3-diamine, 4,4′-oxydianiline, or ethylene diamine. In some examples, a first precursor is vaporized to form a first precursor vapor. The precursor being vaporized may be liquid or solid under standard temperature and pressure conditions (room temperature and atmospheric pressure). The substrate is then exposed to the first precursor vapor. The substrate is also exposed to a second vapor-phase precursor, for example an organic precursor, such as a dianhydride. A dianhydride may be, for example, pyromellitic dianhydride (PMDA) and/or a dithioanhydride, for example, pyromellitic dithioanhydride (PMDTA). The cyclic exposure of the substrate to the two precursors leads to the deposition of an organic material. The method can include additional steps, and may be repeated, but need not be performed in the illustrated sequence nor the same sequence in each repetition, and can be readily extended to more complex vapor deposition techniques.

In various examples, the first precursor may comprise an amine, for example, a diamine, a triamine and/or a tetraamine (e.g., 1,3-diaminopentane (1,3-DAP), cyclohexane-1,3,5-triamine or 2,2-bis(aminomethyl)-1,3-propanediamine).

### Diamines

In an example, a diamine compound of the first precursor according to the current disclosure may comprise at least three carbon atoms. In some embodiments, the diamine is a C2 to C15 compound. In some embodiments, the diamine comprises a halogen. In some embodiments, the two amine groups are attached to different carbon atoms, and the two carbon atoms are non-adjacent.

For example, the diamine compound of the first precursor according to the current disclosure may comprise four carbons and be selected from 1,2-diaminobutane; 1,3-diaminobutane and 2,4-diaminobutane. Thus, in the four-carbon examples, at least one of the amino groups is attached to a carbon atom that is bonded to two other carbon atoms. In other words, at least one of the amino groups is not located at the end of a carbon chain.

The first precursor may comprise a molecule comprising at least two amine groups. In some embodiments, the molecule comprising at least two amine groups comprises at least one primary amine. In some embodiments, the molecule comprising at least two amine groups may comprise two primary amines, three primary amines or four primary amines.

In some examples, first precursor comprising at least two amine groups may be selected from a group comprising 4,4′-oxydianiline; 1,4-diaminobenzene, 2-diaminoethane; 1,3-diaminopropane; 1,4-diaminobutane; 1,5-diaminopentane; 1,2-diaminopropane; 2,3-butanediamine, 2,2-dimethyl-1,3-propanediamine, 1,3-diaminopentane; 1,4-diaminopentane; 2,4-diaminopentane; 2,4-diamino-2,4-dimethylpentane; 1,5-diamino-2-methylpentane; 1,3-diamino-3-methylbutane; 2,5-diamino-2,5-dimethylhexane; 1,4-diamino-4-methylpentane; 1,3-diaminobutane; 1,5-diaminohexane; 1,3-diaminohexane; 1,6-diaminohexane; 2,5-diaminohexane; 1,3-diamino-5-methylhexane; 4,4,4-trifluoro-1,3-diamino-3-methylbutane; 2,4-diamino-2-methylpentane; 4-(1-methylethyl)-1,5-diaminohexane; 3-aminobutanamide; 1,3-diamino-2-ethylhexane; 2,7-diamino-2,7-dimethyloctane; 1,3-diaminobenzene, 1,4-diaminobenzene; 1,6-diaminohexane; decane-1,10-diamine; and/or 4-nitrobenzene-1,3-diamine or cis- or trans-stereoisomers thereof.

In some examples, both amine groups of the diamine may be bonded to a cyclic carbon backbone, or a carbon backbone including carbon-carbon double bonds and/or carbon-carbon triple bonds. In this context, the term “carbon backbone” means the presence of carbon atoms in a main continuous chain or ring-like structure comprising three or more carbon atoms. Such diamines may comprise, for example, one or more of: trans-1,4-diaminocyclohexane; 2,4-diamino-2,4-dimethylpentane; 1,5-diamino-2-methylpentane; 1,3-diamino-3-methylbutane; 2,5-diamino-2,5-dimethylhexane; 1,2-diaminocyclopropane; 1,3-diaminocyclobutane; 1,3-diaminocyclohexane; 1,3-diaminocyclopentane; 1,4-diaminocyclohexane; 1,3-diaminocycloheptane; 1,4-diaminocycloheptane; 2,7-diamino-2,7-dimethyloctane; diaminocyclohexane; 1,3-diaminobenzene and 1,4-diaminobenzene, or cis- or trans-stereoisomers thereof.

In some examples, first precursor may comprise a diamine comprising a carbon chain that is branched. Thus, there is at least one carbon atom which is bonded to three or four other carbon atoms. In some examples, there is one such branching position in the diamine compound. In some examples, there are two such branching positions in the diamine compound. In some examples, there are three or more branching points. In some examples, the side chain from the longer carbon chain is one of a methyl group, an ethyl group, a propyl group, an isopropyl group, a butyl group, or a tert-butyl group, or a combination thereof. In some examples, a side chain of a diamine compound of the first precursor is a straight alkyl chain. In some examples, a side chain of a diamine compound of the first precursor is a branched alkyl chain. In some examples, a side chain of a diamine compound of the first precursor is a cyclic alkyl chain.

In some examples, the diamine compound of the first precursor is a C3 to C11 compound. The number of carbon atoms in the diamine compound typically influences the volatility of the compound such that a higher-weight compound may not be as volatile as a smaller compound. In certain examples, intermediate-sized diamine compounds containing at least five carbon atoms, may have suitable properties for being used as a diamine precursor in the selective deposition processes according to the current disclosure. For example, 1,3-diaminopentane is liquid at room temperature, has a boiling point of 164° C. under atmospheric pressure, a vapor pressure of about 2.22 Torr at 25° C. and reaches a vapor pressure of 1 Torr at temperatures below 20° C. Thus, when 1,3-diaminopentane (1,3-DAP) may be used as a precursor for organic material deposition according to the current disclosure, the precursor vessel does not need to be heated. This may be advantageous for the on-tool lifetime of the precursor, as it may be less prone to degradation during continued use. Further, a liquid precursor has an advantage that precursor vessel loading is less expensive than for solid precursors. In some embodiments, the first precursor comprises 1,3-DAP.

In some examples of the disclosure, the amine groups are attached to non-adjacent carbon atoms. This may have advantages for the availability of the amine groups for reactions with the second precursor. In some examples, there is one carbon atom between the amino group-binding carbon atoms. In some examples, there is at least one carbon atom between the amino group-binding carbon atoms. In some examples, there are two carbon atoms between the amino group-binding carbon atoms. In some examples, there are at least two carbon atoms between the amino group-binding carbon atoms. In some examples, there are three carbon atoms between the amino group-binding carbon atoms. In some examples, there are at least three carbon atoms between the amino group-binding carbon atoms. In some examples, there are four carbon atoms between the amino group-binding carbon atoms. In some examples, there are at least four carbon atoms between the amino group-binding carbon atoms.

In some examples, the first precursor comprises 1,5-diamino-2-methylpentane. Although the vapor pressure of 1,5-diamino-2-methylpentane is lower than that of 1,3-diaminopentane, it is also liquid at ambient temperature, and reaching vapor pressure of 1 Torr requires a moderate temperature of about 40° C.

In some examples, a carbon atom bonded with an amine nitrogen in the diamine compound is bonded to at least two carbon atoms. Thus, in some examples in which the diamine comprises three or more carbons, at least one of the amino groups is not located at the end of a carbon chain. The structure of the diamine compound affects its properties in a vapor deposition process. Branching of a diamine compound, including the number of branches, and the relative position of the amino groups to the branches, may cause the deposited organic material to have different properties. Without limiting the current disclosure to any specific theory, for example steric factors, may lead to certain reactions being preferred. This may offer the possibility to design a deposition process for a given purpose, taking into account for example the thermal budget, organic material growth speed requirements, necessary degree of selectivity, by using different diamine compounds.

In some examples, the diamine compound of the first precursor is an aromatic diamine. In some examples, the aromatic diamine is a diaminobenzene, such as 1,2-diaminobenzene, 1,3-diaminobenzene; 1,4-diaminobenzene; or cis- or trans-stereoisomers thereof. In some examples, the aromatic diamine comprises an alkylamino group in at least one position. For example, the alkylamino group may be a C1 to C3 alkylamino group, such as —CH₂NH₂, —(CH₂)₂NH₂, —(CH₂)₃NH₂, —CH(CH₃)NH₂ or —CH₂CH(CH₃)NH₂.

In some examples, the diamine compound of the first precursor is selected from a group consisting of trans-1,4-diaminocyclohexane; 1,2-diaminocyclopropane; 1,3-diaminocyclobutane; 1,3-diaminocyclohexane; 1,3-diaminocyclopentane; 1,3-diaminocycloheptane; 1,4-diaminocycloheptane; 4,4′-oxydianiline; 1,4-diaminobenzene; 2-diaminoethane; 1,3-diaminopropane; 1,4-diaminobutane; 1,5-diaminopentane; 1,2-diaminopropane; 2,3-butanediamine; 2,2-dimethyl-1,3-propanediamine; 1,3-diaminopentane; 1,4-diaminopentane; 2,4-diaminopentane; 2,4-diamino-2,4-dimethylpentane; 1,5-diamino-2-methylpentane; 1,3-diaminobutane; 1,3-diamino-3-methylbutane; 2,5-diamino-2,5-dimethylhexane; 1,4-diamino-4-methylpentane; 1,3-diaminobutane; 1,5-diaminohexane; 1,3-diaminohexane; 1,6-diaminohexane; 2,5-diaminohexane; 1,3-diamino-5-methylhexane; 4,4,4-trifluoro-1,3-diamino-3-methylbutane; 2,4-diamino-2-methylpentane; 4-(1-methylethyl)-1,5-diaminohexane; 3-aminobutanamide; 1,3-diamino-2-ethylhexane; 2,7-diamino-2,7-dimethyloctane; 1,4-diaminocyclohexane; diaminocyclohexane; 1,3-diaminobenzene; decane-1,10-diamine; 4-nitrobenzene-1,3-diamine and 1,4-diaminobenzene and trans- and cis-stereoisomers thereof. In some examples, the diamine compound comprises a halogen.

### Triamines

In some examples, the first precursor may comprise a triamine compound (e.g., any branched aliphatic or aromatic compound containing three primary amine functional groups) which may be combine with a second precursor (e.g., PMDTA) as disclosed herein to form a passivation layer (e.g., to prevent film formation on a non-growth surface during area selective deposition).

In an example, the triamine may comprise the following structure:

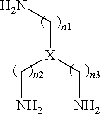

where X is C—R, Si—R, Sn—R, N, P, or As, and n1, n2, and n3 are positive integers.

Providing such molecules may advantageously affect the availability of polymerization sites for the second vapor-phase reactant. The availability of three amine groups in a single molecule, may lead to a denser polymer network, which may reduce the metal migration through the organic material. Such properties may be advantageous in examples utilizing the organic material according to the current disclosure as a passivation layer.

Examples of suitable triamines include 1,2,3-triaminopropane, triamino butane (with amines in carbons 1,2 and 3 or in carbons 1,2 and 4), triamino pentane (especially with amines in carbons 1 and 5, plus in any one of the carbons 2 or 3). Similarly, triamino hexanes may contain amine groups in carbons 1 and 6, as well as in any one of the positions 2, or 3; triamino heptanes may contain amine groups in carbons 1 and 7, as well as in any one of the positions 2, 3 or 4; and triamino octanes may contain amine groups in carbons 1 and 8, as well as in any one of the positions 2, 3 or 4. Further, branched carbon chains, notably tris(aminoethyl) phosphane; tris(aminoethyl) arsane; bis(aminoethyl)aminomethylamine; tris(aminoethyl) silane; tris(aminoethyl) stannane; tris(aminoethyl)methylsilane; 2-methylbenzene-1,3,5-triamine; pentane-1,2,4-triamine; cyclohexane-1,3,5-triamine; pentane-1,3,5-triamine; tris(2-aminoethyl)amine; 2-aminomethyl-1,3-diaminopropane; 2-(aminomethyl) propane-1,3-diamine; propane-1,2,3-triamine; 2-(aminomethyl) butane-1,4-diamine; 2-aminomethyl-1,4-diaminobutane (or alternatives having the two amino groups elsewhere in the butane chain); tris(2-aminoethyl)phosphane; 2-aminomethyl-1,5-diaminopentane (or alternatives having the two amino groups elsewhere in the pentane chain); 3-aminomethyl-1,5-diaminopentane (or alternatives having the two amino groups elsewhere in the pentane chain); 2-aminomethyl-1,6-diaminohexane (or alternatives having the two amino groups elsewhere in the hexane chain); 3-aminomethyl-1,6-diaminohexane (or alternatives having the two amino groups elsewhere in the hexane chain); 3-aminoethyl-1,6-diaminohexane (or alternatives having the two amino groups elsewhere in the hexane chain), or cis or trans stereoisomers thereof may be an alternative for certain examples. Also, aromatic triamines, such as 2-methylbenzene-1,3,5-triamine, and/or 1,3,5-triaminobenzene or cis or trans stereoisomers thereof, may be an alternative for certain examples.

In some examples, the organic film comprises a polymer. In some examples, the polymer deposited is a polyimide. In some examples, the polymer deposited is a polyamide. In some examples, the polymer deposited is a polyamic acid. Thus, in some examples, the organic material comprises polyimide. In some examples, the organic material consists substantially only of polyimide. In some examples, the organic material comprises polyamic acid. In some examples, the organic material consists substantially only of amide and polyimide. In some examples, the organic material is deposited at temperatures below 190° C., and subsequently heat-treated at a temperature of about 190° C. or higher (such as 200° C. or 210° C.) to increase the proportion of the organic material from polyamic acid to polyimide. Other examples of deposited polymers include dimers, trimers, polyurethanes, polythioureas, polyesters, polyimines, other polymeric forms or mixtures of the above materials.

### Tetramines

The first precursor may comprise a tetraamine which may be combine with a second precursor (e.g., PMDTA) as disclosed herein to form a passivation layer (e.g., to prevent film formation on a non-growth surface during area selective deposition). The use of tetraamines may produce a cross-linked version of polyimide that may improve selectivity relative to versions that lack cross-linking.

The tetraamine is defined as a molecule that contains four —NH2 groups attached to a hydrocarbyl group containing from 1 to 12 carbon atoms. In some examples, the hydrocarbyl group may contain other elements, such as O, N, or S, that are linking hydrocarbyl subunits together.

In some embodiments, the hydrocarbyl group comprises an alkyl chain that can be branched or unbranched. In some embodiments, the hydrocarbyl group comprises an arene. In some embodiments, the hydrocarbyl group comprises both alkyl and aryl groups. In some embodiments, two or more of the —NH2 groups are attached to the same carbon atom. In some embodiments, two or more of the —NH2 groups are attached to adjacent carbon atoms. In some embodiments, two or more of the —NH2 groups are attached to non-adjacent carbon atoms. In some embodiments, one or more of the —NH2 groups are replaced by an —NHR group where R is a hydrocarbyl group containing 1 to 6 carbon atoms. In some embodiments, one or more of the —NH2 groups are replaced by an ═NH group, i.e. an imino group.

In some embodiments the tetraamine is selected from but not limited to: 2,2-bis(aminomethyl)-1,3-propanediamine; 1,2,3,4-butanetetramine; 3,3-bis(2-aminoethyl)-1,5-pentanediamine; 2,4-bis(aminomethyl)-1,5-pentanediamine; 2,3-dimethyl-1,2,3,4-butanetetramine; butanediimidamide; pentanediimidamide; hexanediimidamide; heptanediimidamide; octanediimidamide; nonanediimidamide; and/or decanediimidamide.

### Cyclic Compounds

The first vapor-phase reactant comprises a cyclic compound comprising at least two primary amine groups. In some embodiments, the cyclic compound comprises a bicyclic ring. In some embodiments, the bicyclic compound contains fused rings. In some embodiments, the bicyclic compound contains separate rings. In some embodiments, the cyclic compound comprises a single ring with at least two NH2-containing substituents. In some embodiments, the cyclic compound comprises a carbocycle. In some embodiments, the carbocycle is a C3 to C8 ring. In some embodiments, the carbocycle is a 3-membered ring. In some embodiments, the carbocycle is a 4-membered ring. In some embodiments, the carbocycle is a 5-membered ring. In some embodiments, the carbocycle is a 6-membered ring. In some embodiments, the carbocycle is a 7-membered ring. In some embodiments, the carbocycle is an 8-membered ring. In some embodiments, the carbocycle is aliphatic (i.e. an alicyclic compound). An alicyclic carbocycle may be saturated or unsaturated.

In some embodiments, the cyclic compound comprises an aromatic ring. In some embodiments, the cyclic compound does not comprise an aromatic ring. In some embodiments, the cyclic compound does not comprise p-phenylenediamine. In some embodiments, the cyclic compound comprises an alicyclic ring. In some embodiments, the cyclic compound comprises a six-membered carbocycle comprising two primary amine groups, bonded directly or indirectly to positions 1 and 4 of the carbon ring, respectively. In some embodiments, the cyclic compound comprises a six-membered carbocycle comprising two primary amine groups, bonded directly to positions 1 and 4 of the carbon ring, respectively. In some embodiments, the cyclic compound comprises a six-membered carbocycle comprising three primary amine groups, bonded directly or indirectly to positions 1, 3 and 5 of the carbon ring, respectively. In some embodiments, the cyclic compound comprises a six-membered carbocycle comprising three primary amine groups, bonded directly to positions 1, 3 and 5 of the carbon ring, respectively. In some embodiments, the cyclic compound comprises at least one of cyclopentanedialkanamine, cyclohexanedialkanamine, cyclopentadienedialkanamine, benzenedialkanamine, cyclopentanetrialkanamine, cyclohexanetrialkanamine, cyclopentadienetrialkanamine and benzenetrialkanamine. Each alkyl of said alkanamines may be independently selected from methyl, ethyl, propyl (including n-propyl and isopropyl) and butyl (including n-butyl, sec-butyl, isobutyl and tert-butyl).

In some embodiments, the non-aromatic cyclic diamine compound is a trans isomer of the compound. In some embodiments, the non-aromatic cyclic diamine compound is a cis isomer of the compound. In some embodiments, the non-aromatic cyclic diamine compound is a mixture of cis and trans isomers of the compound. Without limiting the current disclosure to any specific theory, trans isomers of the cyclic compounds may have more desired reactivity and usability in the processes according to the current disclosure.

In some embodiments, the cyclic compound is selected from a group consisting of 1,3-cyclopentanediamine, 3,5-cyclopentadiene-1,3-diamine, 2,4-cyclopentadiene-1,3-diamine, 1,3-cyclopentanedimethanamine, 3,5-cyclopentadiene-1,3-dimethanamine, 2,4-cyclopentadiene-1,3-dimethanamine, 1,4-diaminocyclohexane, 1,3-cyclohexanediamine, 1,2-cyclohexanediamine, 1,4-cyclohexanedimethanamine, 1,3-cyclohexanedimethanamine, 1,2-cyclohexanedimethanamine, 1,4-cyclohexanediethanamine, 1,3-cyclohexanediethanamine, 1,2-cyclohexanediethanamine, 1,2,3-cyclopentanetriamine, 1,2,4-cyclopentanetriamine, 1,3-cyclopentadiene-1,2,4-triamine, 1,2,3-cyclohexanetriamine, 1,2,4-cyclohexanetriamine, 1,3,5-cyclohexanetriamine, 1,3,5-cyclohexanetrimethanamine, p-phenylenediamine, m-phenylenediamine, o-phenylenediamine, 1,4-benzenedimethanamine, 1,3-benzenedimethanamine, 1,2-benzenedimethanamine, 1,2,3-benzenetriamine, 1,2,4-benzenetriamine, 1,3,5-benzenetriamine, 1,2,3-benzenetrimethanamine, 1,2,4-benzenetrimethanamine and 1,3,5-benzenetrimethanamine.

In some embodiments, the first precursor is selected from compounds having a cyclopentane, cyclopentadiene, cyclohexane or a benzene ring and two primary amine containing substituents, wherein the amine containing substituents are independently selected from —NH2, —CH2NH2 and —CH2CH2NH2. Thus, the substituents may be the same, such as both substituents are —NH2, or both substituents are —CH2NH2 or both substituents are —CH2CH2NH2. The substituents may be different. For example, one substituent may be —NH2, and the second one —CH2NH2. One substituent may be —NH2, and the second one-CH2CH2NH2. One substituent may be —CH2CH2NH2, and the second one —CH2NH2.

In some embodiments, the first precursor is selected from compounds having a cyclopentane, cyclopentadiene, cyclohexane or a benzene ring and three primary amine containing substituents, wherein the amine containing substituents are independently selected from —NH2, —CH2NH2 and —CH2CH2NH2. Thus, the substituents may be the same, such as all three substituents are —NH2, or all three substituents are —CH2NH2 or all three substituents are —CH2CH2NH2. The substituents may be different. For example, one substituent may be —NH2, and the second one —CH2NH2 and the third one —CH2CH2NH2. One substituent may be —NH2, and the two other substituents —CH2NH2. One substituent may be —CH2NH2, and the two other substituents —NH2. One substituent may be —NH2, and the two other substituents —CH2CH2NH2. One substituent may be —CH2CH2NH2, and the two other substituents-NH2. One substituent may be —CH2NH2, and the two other substituents —CH2CH2NH2. One substituent may be —CH2CH2NH2, and the two other substituents —CH2NH2.

In some examples a reactant may have a vapor pressure greater than about 0.5 Torr, 0.1 Torr, 0.2 Torr, 0.5 Torr, 1 Torr or greater at a temperature of about 20° C. or room temperature. In some examples a reactant may have a boiling point less than about 400° C., less than 300° C., less than about 250° C., less than about 200° C., less than about 175° C., less than about 150° C., or less than about 100° C.

### Polyamide Deposition

In some examples deposition processes taught herein may comprise deposition of a polyamide thin film. In some examples such a deposition process may comprise a vapor deposition process. In some examples such a deposition process may comprise a molecular layer deposition (MLD) process. In some examples such deposition processes may be a selective deposition process. However, in some examples such a deposition processes may be a nonselective deposition process.

In some examples a first precursor is vaporized to form a first precursor vapor. The reactant being vaporized may be liquid or solid under standard temperature and pressure conditions (room temperature and atmospheric pressure). In some examples, the first precursor being vaporized comprises an organic precursor, such as an organochloride, for example adipoyl chloride (AC). In some examples a reactant may comprise an organic precursor selected from the group of oxalyl chloride (I), malonyl chloride, and fumaryl chloride.

In some examples the first precursor may be vaporized at a first temperature to form the first vapor phase precursor. In some examples the first precursor vapor is transported to the substrate through a gas line at a second temperature. In some examples the second transportation temperature is higher than the first vaporization temperature. In some examples the substrate is contacted with a first vapor phase precursor, or reactant, for a first exposure period. In some examples the substrate may be contacted with the first vapor phase precursor at a third temperature that is higher than the first temperature.

In some examples the first precursor exposure period is from about 0.05 seconds to about 5.0 seconds, about 0.1 seconds to about 3 seconds or about 0.2 seconds to about 1.0 seconds. The optimum exposure period can be readily determined by the skilled artisan based on the particular circumstances.

In some examples a second organic reactant is vaporized to form a second precursor vapor. The reactant being vaporized may be liquid or solid under standard temperature and pressure conditions (room temperature and atmospheric pressure). In some examples, the reactant being vaporized comprises an organic precursor, such as an organic amine, for example ethylene diamine (EDA). In some examples a reactant may comprise an organic precursor selected from the group of 1,2-diaminoethane (1), 1,3-diaminopropane (1), 1,4-diaminobutane (1), 1,5-diaminopentane (1), 1,2-diaminopropane (1), 2,3-butanediamine, 2,2-dimethyl-1,3-propanediamine (1).

### Second Precursor

In some examples, the second precursor may be an anhydride. The second precursor may contact the first surface prior to, concurrent with or subsequent to the first surface being contacted with the first precursor.

In some examples, the second precursor comprises a compound including two thioanhydride groups comprising a structure represented by the general formula (1):

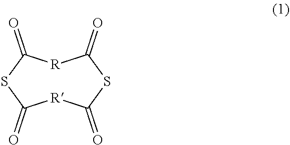

where R and R′ can independently comprise a hydrocarbyl group. In certain examples, at least one of the hydrocarbyl groups may independently comprise one or more of O, N, or S, or a combination thereof. In an example, R and/or R′ may be independently limited to compounds in the range of C1 to C8, C1 to C10 or C1 to C15, or a combination thereof.

In some examples, the second precursor comprises a compound including two thioanhydride groups comprising a structure represented by the general formula (2):

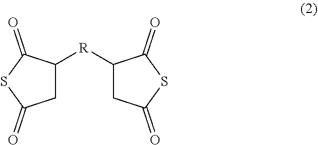

where R can comprise a hydrocarbyl group. In certain examples, the hydrocarbyl group may comprise one or more of O, N, or S, or a combination thereof. In an example, R may be limited to compounds in the range of C1 to C8, C1 to C10 or C1 to C15.

In some examples, the second precursor comprises a compound including one thioanhydride group and one anhydride group comprising a structure represented by the general formula (3):

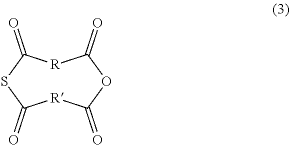

where R and R′ can independently comprise a hydrocarbyl group. In certain examples, at least one of the hydrocarbyl groups may independently comprise one or more of O, N, or S, or a combination thereof. In an example, R and/or R′ may be independently limited to compounds in the range of C1 to C8, C1 to C10 or C1 to C15, or a combination thereof.

In some examples, the second precursor comprises a compound including one thioanhydride group and one anhydride group comprising a structure represented by the general formula (4):

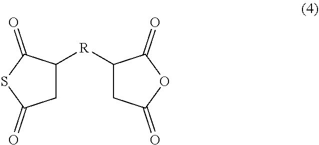

where R can comprise a hydrocarbyl group. In certain examples, the hydrocarbyl group may comprise one or more of O, N, or S, or a combination thereof. In an example, R may be limited to compounds in the range of C1 to C8, C1 to C10 or C1 to C15.

In some examples, the second precursor comprises a compound including at least one thioanhydride group comprising a structure represented by the general formula (5):

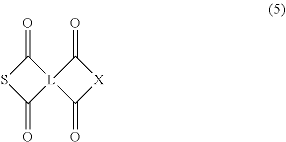

where L is a tetravalent hydrocarbyl group that optionally comprises one or more of O, N, and/or S, or a combination thereof; and where X is selected from the group consisting of S or O.

In some examples, the second precursor comprises a compound including two or more anhydride groups comprising a structure represented by the general formula (6):

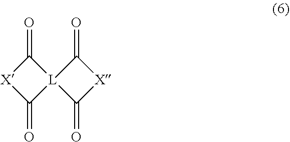

where L is a tetravalent hydrocarbyl group that optionally comprises one or more of O, N, and/or S; and where X′ and X″ are independently selected from the group consisting of S, Se, Te, NH, NR″ or O, where R″ may be limited to C1 to C6 compounds.

In some examples, the second precursor comprises a compound comprising a structure represented by the general formula (7):

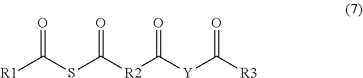

where R1, R2 and R3 can independently comprise a hydrocarbyl group. In certain examples, at least one of the hydrocarbyl groups may independently comprise one or more of O, N, or S, or a combination thereof; where Y is selected from the group consisting of S, Se, Te, NH, NR″ or O; where R″ may be limited to C1 to C6 compounds. In an example, R1, R2 and/or R3 may be independently limited to compounds in the range of C1 to C8, C1 to C10 or C1 to C15, or a combination thereof.

Table 1 includes non-limiting examples of compounds according to formulas (1)-(7):

TABLE 1

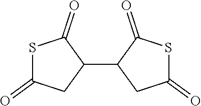 [SMILES: O=C1CC(C2CC(=O)SC2=O)C(=O)S1]

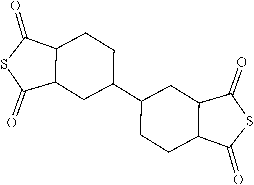 [SMILES: O=C1SC(=O)C2CC(C3CCC4C(=O)SC(=O)C4C3)CCC12]

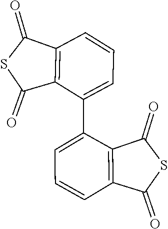 [SMILES: O=C1SC(=O)c2c1cccc2-c1cccc2c1C(=O)SC2=O]

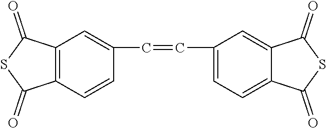 [SMILES: O=C1SC(=O)c2cc(C=Cc3ccc4c(c3)C(=O)SC4=O)ccc21]

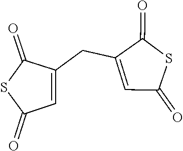 [SMILES: O=C1C=C(CC2=CC(=O)SC2=O)C(=O)S1]

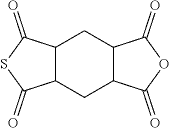 [SMILES: O=C1OC(=O)C2CC3C(=O)SC(=O)C3CC12]

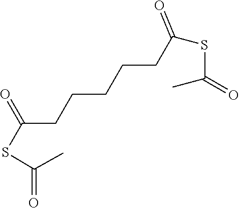 [SMILES: CC(=O)SC(=O)CCCCCC(=O)SC(C)=O]

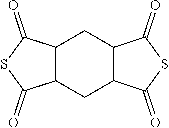 [SMILES: O=C1SC(=O)C2CC3C(=O)SC(=O)C3CC12]

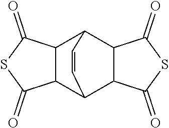 [SMILES: O=C1SC(=O)C2C3C=CC(C12)C1C(=O)SC(=O)C31]

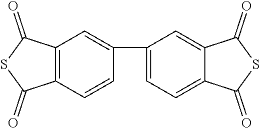 [SMILES: O=C1SC(=O)c2cc(-c3ccc4c(c3)C(=O)SC4=O)ccc21]

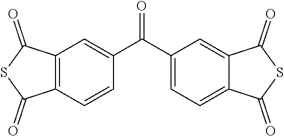 [SMILES: O=C(c1ccc2c(c1)C(=O)SC2=O)c1ccc2c(c1)C(=O)SC2=O]

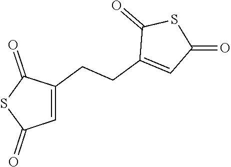 [SMILES: O=C1C=C(CCC2=CC(=O)SC2=O)C(=O)S1]

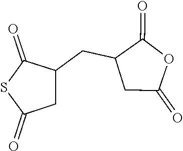 [SMILES: O=C1CC(CC2CC(=O)SC2=O)C(=O)O1]

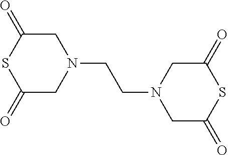 [SMILES: O=C1CN(CCN2CC(=O)SC(=O)C2)CC(=O)S1]

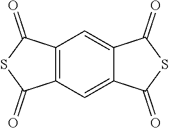 [SMILES: O=c1sc(=O)c2cc3c(=O)sc(=O)c3cc12]

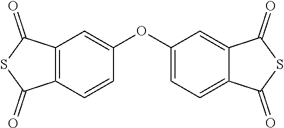 [SMILES: O=C1SC(=O)c2cc(Oc3ccc4c(c3)C(=O)SC4=O)ccc21]

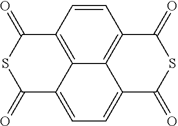 [SMILES: O=C1SC(=O)c2ccc3c4c(ccc1c24)C(=O)SC3=O]

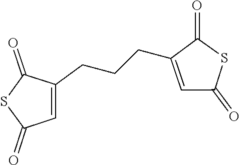 [SMILES: O=C1C=C(CCCC2=CC(=O)SC2=O)C(=O)S1]

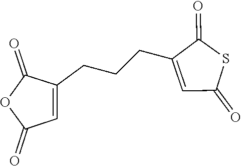 [SMILES: O=C1C=C(CCCC2=CC(=O)SC2=O)C(=O)O1]

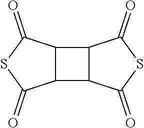 [SMILES: O=C1SC(=O)C2C1C1C(=O)SC(=O)C21]

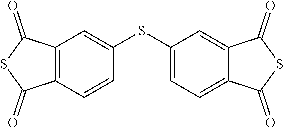 [SMILES: O=C1SC(=O)c2cc(Sc3ccc4c(c3)C(=O)SC4=O)ccc21]

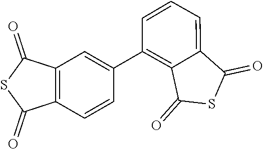 [SMILES: O=C1SC(=O)c2cc(-c3cccc4c3C(=O)SC4=O)ccc21]

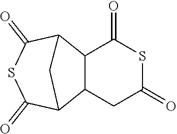 [SMILES: O=C1CC2C3CC(C(=O)SC3=O)C2C(=O)S1]

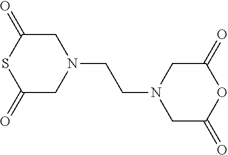 [SMILES: O=C1CN(CCN2CC(=O)SC(=O)C2)CC(=O)O1]

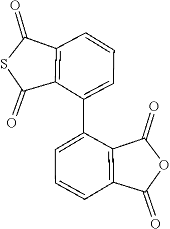 [SMILES: O=C1OC(=O)c2c1cccc2-c1cccc2c1C(=O)SC2=O]

In some examples a polyamide film of a desired thickness is deposited on a substrate. The skilled artisan will appreciate that deposition of a polyamide film is the result of the above-described contacting actions, rather than a separate action. In some examples, the above-described contacting actions may be considered a deposition cycle. In some examples a deposition cycle may repeated until an organic film of a desired thickness is selectively deposited. Such a deposition cycle can be repeated until a film of sufficient thickness is left on the substrate and the deposition is ended. The deposition cycle can include additional acts, need not be in the same sequence nor identically performed in each repetition, and can be readily extended to more complex vapor deposition techniques. For example, a deposition cycle can include additional reactant supply processes, such as the supply and removal (relative to the substrate) of additional reactants in each cycle or in selected cycles. Though not shown, the process may additionally comprise treating the deposited film to form a polymer (for example, UV treatment, annealing, etc.).

In some examples of the selective deposition, a passivation layer is selectively deposited on a first surface of the substrate relative to a second surface of the substrate by contact with a first precursor and a second precursor. In some examples, as described above the first precursor is an amine, such as a diamine, triamine, tetramine, cyclic amine, or the like or a combination thereof.

### Subsequent Processing

In some examples further processing may be carried out subsequent to an organic film deposition process, such as a selective deposition process as described herein. For example, in some examples the substrate may be subjected to an etch process to remove at least a portion of the deposited organic film. In some examples an etch process subsequent to selective deposition of the organic film may remove deposited organic material from both the first surface and the second surface of the substrate. In some examples the etch process may be isotropic.

In some examples the etch process may remove the same amount, or thickness, of material from the first and second surfaces. That is, in some examples the etch rate of the organic material deposited on the first surface may be substantially similar to the etch rate of the organic material deposited on the second surface. Due to the selective nature of the deposition processes described herein, the amount of organic material deposited on the second surface of the substrate may be substantially less than the amount of material deposited on the first surface of the substrate. Therefore, an etch process may completely remove deposited organic material from the second surface of the substrate while deposited organic material may remain on the first surface of the substrate.

In some examples the etch process may comprise an etch process known in the art, for example a dry etch process such as a plasma etch process. In some examples the etch process may comprise exposing the substrate to hydrogen atoms, hydrogen radicals, hydrogen plasma, or combinations thereof. For example, in some examples the etch process may comprise exposing the substrate to a plasma generated from H₂ using a power from about 10 W to about 5000 W, from about 25 W to about 2500 W, from about 50 W to about 500 W, or from about 100 W to about 400 W. In some examples the etch process may comprise exposing the substrate to a plasma generated using a power from about 1 W to about 1000 W, from about 10 W to about 500 W, from about 20 W to about 250 W, or from about 25 W to about 100 W.

In some examples the etch process may comprise exposing the substrate to a plasma. In some examples the plasma may comprise reactive species such as oxygen atoms, oxygen radicals, oxygen plasma, or combinations thereof. In some examples the plasma may also comprise noble gas species in addition to reactive species, for example Ar or He species. In some examples the plasma may comprise noble gas species without reactive species. In some instances, the plasma may comprise other species, for example nitrogen atoms, nitrogen radicals, nitrogen plasma, or combinations thereof. In some examples the etch process may comprise exposing the substrate to an etchant comprising oxygen, for example 03. In some examples the substrate may be exposed to an etchant at a temperature of between about 30° C. and about 500° C., or between about 100° C. and about 400° C. In some examples the etchant may be supplied in one continuous pulse or may be supplied in multiple shorter pulses.

A skilled artisan can readily determine the optimal exposure time, temperature, and power for removing the desired amount of deposited organic material from the substrate.

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various processes, systems, and configurations, and other features, functions, acts, and/or properties disclosed herein, as well as any and all equivalents thereof.

1. A process for forming a passivation layer on a substrate, comprising:
providing the substrate in a reaction chamber, the substrate comprising a first surface and a second surface;
contacting the substrate with a first precursor comprising an amine compound comprising at least two amine groups; and
contacting the substrate with a second precursor comprising at least one thioanhydride, wherein contacting the substrate with the first and second precursors forms the film selectively on the first surface relative to the second surface.

2. The process of claim 1, wherein the passivation layer comprises a polyimide film.

3. The process of claim 2, wherein the passivation layer comprises a polyimide film pyromellitic dithioanhydride.

4. The process of claim 1, wherein the contacting operations comprise a deposition cycle, the process comprising one or more deposition cycles.

5. The process of claim 4, further comprising repeating the contacting operations until a passivation layer of a desired thickness has been formed.

6. The process of claim 1, wherein the first surface is a metal carbide, metal oxide, metal nitride, metal boride, elemental metal, metallic surface, amorphous carbon, or a combination thereof.

7. The process of claim 1, wherein the first surface comprises a metal comprising aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr) or vanadium (V), or a combination thereof.

8. The process of claim 1, wherein the first surface is a dielectric surface comprising SiCOx, SiOx, silicon, SiO2, zirconium oxide (ZrO2), hafnium oxide (HfO2), aluminum oxide (Al2O3), titanium nitride (TiN) and titanium oxide (TiO2), or aluminum nitride (AlN), or a combination thereof.

9. The process of claim 1, wherein the first surface comprises RuOx, NiOx, CoOx, NbOx, MoOx, WOx, NbBx, NbCx, WNCx, TaN, or TiN, or a combination thereof.

10. The process of claim 1, wherein the second surface comprises a passivation blocking layer formed thereon.

11. The process of claim 10, wherein the second surface comprises a metal comprising aluminum (Al), copper (Cu), tungsten (W), cobalt (Co), nickel (Ni), niobium (Nb), iron (Fe), molybdenum (Mo), indium (In), gallium (Ga), manganese (Mn), zinc (Zn), ruthenium (Ru), titanium (Ti), tantalum (Ta), chromium (Cr) or vanadium (V), or a combination thereof.

12. The process of claim 10, wherein the second surface is a dielectric surface comprising SiCOx, SiOx, silicon, SiO2, zirconium oxide (ZrO2), hafnium oxide (HfO2), aluminum oxide (Al2O3), titanium nitride (TiN) and titanium oxide (TiO2), or aluminum nitride (AlN), or a combination thereof.

13. The process of claim 10, wherein the second surface comprises RuOx, NiOx, CoOx, NbOx, MoOx, WOx, NbBx, NbCx, WNCx, TaN, or TiN, or a combination thereof.

14. The process of claim 10, wherein the passivation blocking layer comprises a self-assembled monolayer (SAM) or an alkylsilane having at least one alkoxy group bonded to a silicon atom.

15. The process of claim 1, wherein the first precursor comprises a diamine, a triamine, a tetraamine, a cyclic compound comprising at least two primary amines, or a combination thereof.

16. The process of claim 1, wherein the second precursor comprises a compound including two thioanhydride groups comprising a structure represented by the general formula (1): 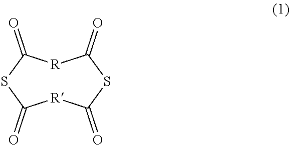
where R and R′ independently comprise hydrocarbyl groups.

17. The process of claim 16, wherein at least one of the hydrocarbyl groups independently comprises one or more of O, N, or S, or a combination thereof.

18. The process of claim 1, wherein the second precursor comprises a compound including two thioanhydride groups comprising a structure represented by the general formula (2): 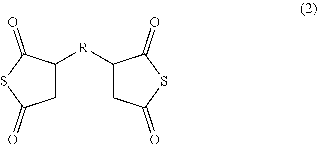
where R comprises a hydrocarbyl group.

19. The process of claim 18, wherein the hydrocarbyl group comprises one or more of O, N, or S, or a combination thereof.

20. The process of claim 1, wherein the second precursor comprises a compound including one thioanhydride group and one anhydride group comprising a structure represented by the general formula (3): 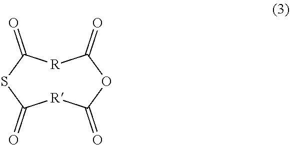
where R and R′ independently comprise hydrocarbyl groups.

21. The process of claim 20, wherein at least one of the hydrocarbyl groups independently comprises one or more of O, N, or S, or a combination thereof.

22. The process of claim 1, wherein the second precursor comprises a compound including one thioanhydride group and one anhydride group comprising a structure represented by the general formula (4): 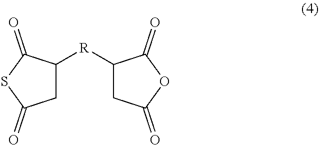
where R comprises a hydrocarbyl group.

23. The process of claim 22, wherein the hydrocarbyl group comprises one or more of O, N, or S, or a combination thereof.

24. The process of claim 1, wherein the second precursor comprises a compound including at least one thioanhydride group comprising a structure represented by the general formula (5): 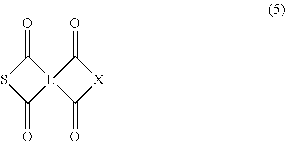
where L is a tetravalent hydrocarbyl group that optionally comprises one or more of O, N, or S, or a combination thereof; and where X is selected from the group consisting of S or O.

25. The process of claim 1, wherein the second precursor comprises a compound including two or more anhydride groups comprising a structure represented by the general formula (6): 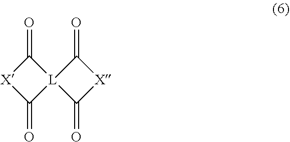
where L is a tetravalent hydrocarbyl group that optionally comprises one or more of O, N, or S, or a combination thereof; and where X′ and X″ are independently selected from the group consisting of S, Se, Te, NH, NR″ or O, where R″ is a C1 to C6 compound.

26. The process of claim 1, wherein the second precursor comprises a compound represented by the general formula (7): 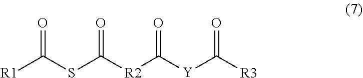
where R1, R2 and R3 independently comprise hydrocarbyl groups that optionally comprises one or more of O, N, or S, or a combination thereof; and where Y is selected from the group consisting of S, Se, Te, NH, NR″ or O, where R″ is a C1 to C6 compound.

27. The process of claim 1, further comprising selectively depositing a material on the second surface of the substrate relative to the passivation layer.

28. The process of claim 27, wherein the material is a first dielectric and the second surface is a second dielectric.

29. The process of claim 27, wherein the material is a dielectric and the second surface is a metal.

30. The process of claim 27, wherein the material is a metal and the second surface is a dielectric.

31. The process of claim 27, wherein the material is a metal and the second surface is a metal comprising a conductive metal nitride.
